(19) United States
(12) Patent Application Publication
(10) Pub. No.: US 2014/0080291 A1
(43) Pub. Date: Mar. 20, 2014

(54) METHOD FOR PRODUCING A GRAPHENE NANO-RIBBON

(71) Applicant: Panasonic Corporation, Osaka (JP)

(72) Inventors: Katsuya NOZAWA, Osaka (JP); Akihiro ODAGAWA, Osaka (JP)

(73) Assignee: PANASONIC CORPORATION, Osaka (JP)

(21) Appl. No.: 14/025,718

(22) Filed: Sep. 12, 2013

(30) Foreign Application Priority Data
Sep. 13, 2012 (JP) 2012-201158

(51) Int. Cl. H01L 21/02

(52) U.S. Cl. CPC H01L 21/02636; H01L 21/02527; H01L 21/02609
USPC 438/478

(57) ABSTRACT

A method for producing a graphene nanoribbon is disclosed. This production method includes the steps of: forming a crystalline catalytic metal layer composed of copper or nickel on a (110) plane or a (112) plane of a MgAl₂O₄ single-crystal substrate or a MgO single-crystal substrate, with a thickness of the crystalline catalytic metal layer being controlled and with a crystal orientation of the crystalline catalytic metal layer being controlled so that the crystal orientation coincides with a crystal orientation of the single-crystal substrate; forming a cap layer composed of an oxide on the formed catalytic metal layer; exposing a {111} plane of the crystalline catalytic metal layer as a side wall by etching a stack including the substrate, the catalytic metal layer, and the cap layer; and growing graphene selectively on the exposed side wall by chemical vapor deposition.

### BACKGROUND OF THE INVENTION

1. Field of the Invention

The present invention relates to a method for producing a graphene nanoribbon, and a method for producing a transistor.

2. Description of Related Art

Graphene is a molecule in the form of a sheet consisting of a hexagonal lattice of carbon atoms that extends over the sheet. Narrowly-defined graphene is composed of a single layer of the sheet (single atomic layer). Also, a stack of several layers of the sheet has characteristics similar to those of a single layer of the sheet. Therefore, broadly-defined graphene includes the single atomic layer and the stack of the several atomic layers. In the present specification, “graphene” means the broadly-defined graphene unless otherwise specified.

A graphene ribbon is a ribbon-shaped material formed by limiting the length in one direction (the width) of graphene molecule which is in the form of a sheet or a stack of sheets. Due to its geometric effect, a graphene ribbon has anisotropy in various physical properties such as electrical properties, optical properties, and mechanical properties. For example, electric current flows through a graphene ribbon in a direction in which the ribbon extends, while electric current does not flow in a direction (width direction) perpendicular to the direction in which the ribbon extends. In addition, for example, a graphene ribbon has optical polarization properties. Various devices including a graphene ribbon as an elementary component and utilizing such anisotropy can be built.

A graphene ribbon having a limited width of 100 nm or less is called a graphene nanoribbon. The graphene nanoribbon has a band gap. By contrast, a mere graphene does not have a band gap. The smaller the width of the ribbon is, the greater the value of the band gap is. For example, in order to achieve a band gap of 0.2 eV or more which is suitable for application to transistors, the width of the graphene nanoribbon needs to be 10 nm or less (see F. Schwierz, “Graphene transistors”, Nature Nanotechnology, vol. 5, pp. 487-496 (2010)).

The basic structure of graphene is a hexagonal lattice of carbon atoms (see FIGS. 1 and 2). Based on the orientation of the hexagonal lattice, the structure of the edge portion (the edges in the width direction) of a graphene ribbon is categorized into two types of structures, a zigzag type structure shown in FIG. 1 and an armchair type structure shown in FIG. 2. In FIGS. 1 and 2, the right/left direction on the sheet of paper is a direction in which the ribbon extends. Some physical properties such as electrical conductivity and magnetic properties in the edge portion of a graphene ribbon greatly vary depending on the structure of the edge portion, unlike those in the central portion over which the hexagonal lattice extends. In a graphene nanoribbon, the proportion of the edge portion is large, and therefore, the influence of the structure of the edge portion is particularly significant. There are graphene nanoribbons having the same width but exhibiting different physical properties due to difference in the structure of the edge portion. Therefore, in the case where a graphene nanoribbon is applied to an electronic device such as a transistor, the structure of the edge portion needs to be properly controlled (a zigzag type structure or an armchair type structure needs to be selectively formed).

Examples of conventional methods for producing graphene nanoribbons include: a method in which graphene is processed using photolithography or electron beam lithography (Melinda Y. Han et al., “Energy Band-Gap Engineering of Graphene Nanoribbons”, Physical Review Letters, vol. 98, 206805 (2007)); and a method in which a carbon nanotube is cut open and processed into a ribbon (Dmitry V. Kosynkin et al., “Longitudinal unzipping of carbon nanotubes to form graphene nanoribbons”, Nature, vol. 458, pp. 872-876 (2009)). WO 2011/025045 A1 discloses a technique for controlling the orientation of the hexagonal lattice of graphene.

### SUMMARY OF THE INVENTION

One non-limiting exemplary embodiment of the present disclosure provides a graphene nanoribbon production method by which a graphene nanoribbon having a controlled width and having an edge portion with a controlled structure can be formed at a desired position on a substrate.

Additional benefits and advantages of the disclosed embodiments will be apparent from the specification and Figures. The benefits and/or advantages may be individually provided by the various embodiments and features of the specification and drawings disclosure, and need not all be provided in order to obtain one or more of the same.

In one general aspect, the techniques disclosed here feature a method for producing a graphene nanoribbon, the method including the steps of: forming a crystalline catalytic metal layer composed of copper or nickel on a (110) plane or a (112) plane of a MgAl₂O₄ single-crystal substrate or a MgO single-crystal substrate, with a thickness of the crystalline catalytic metal layer being controlled and with a crystal orientation of the crystalline catalytic metal layer being controlled so that the crystal orientation coincides with a crystal orientation of the single-crystal substrate; forming a cap layer composed of an oxide on the formed catalytic metal layer; exposing a {111} plane of the crystalline catalytic metal layer as a side wall by etching a stack including the substrate, the catalytic metal layer, and the cap layer; and growing graphene selectively on the exposed side wall by chemical vapor deposition.

These general and specific aspects may be implemented using a system, a method, a computer program, and any combination of systems, methods, and computer programs.

### BRIEF DESCRIPTION OF THE DRAWINGS

FIG. 1 is a schematic diagram for illustrating a graphene nanoribbon (zigzag type graphene nanoribbon) in which the structure of the edge portion in the width direction is of the zigzag type.

FIG. 2 is a schematic diagram for illustrating a graphene nanoribbon (armchair type graphene nanoribbon) in which the structure of the edge portion in the width direction is of the armchair type.

FIGS. 3A to 3C are cross-sectional views schematically showing steps in the graphene nanoribbon fabrication in Embodiment 1.

FIGS. 4A and 4B are cross-sectional views schematically showing steps subsequent to the steps of FIGS. 3A to 3C in the graphene nanoribbon fabrication in Embodiment 1.

FIGS. 5A and 5B are cross-sectional views schematically showing steps subsequent to the steps of FIGS. 4A and 4B in the graphene nanoribbon fabrication in Embodiment 1.

FIG. 6 is a cross-sectional view schematically showing steps subsequent to the steps of FIGS. 5A and 5B in the graphene nanoribbon fabrication in Embodiment 1.

FIG. 7 is a schematic diagram showing an example of an atomic arrangement of a catalytic metal on which a graphene nanoribbon having an edge portion with a zigzag type structure grows.

FIG. 8 is a schematic diagram showing an example of an atomic arrangement of a catalytic metal on which a graphene nanoribbon having an edge portion with an armchair type structure grows.

FIG. 9 is a schematic diagram showing an example of graphene formed on the atomic arrangement shown in FIG. 7.

FIG. 10 is a schematic diagram showing an example of graphene formed on the atomic arrangement shown in FIG. 8.

FIGS. 11A to FIG. 18D are schematic diagrams showing an example of a method for fabricating a transistor, which is an example of application of a graphene nanoribbon obtained by the production method of the present disclosure.

FIGS. 19A to 19C are cross-sectional views schematically showing steps in the graphene nanoribbon fabrication in Embodiment 3.

FIGS. 20A and 20B are cross-sectional views schematically showing steps subsequent to the steps of FIGS. 19A to 19C in the graphene nanoribbon fabrication in Embodiment 3.

FIG. 21 is a cross-sectional view schematically showing a step subsequent to the step of FIGS. 20A and 20B in the graphene nanoribbon fabrication in Embodiment 3.

FIG. 22 is a cross-sectional view schematically showing a step subsequent to the step of FIG. 21 in the graphene nanoribbon fabrication in Embodiment 3.

FIG. 23 is a cross-sectional view schematically showing a step subsequent to the step of FIG. 22 in the graphene nanoribbon fabrication in Embodiment 3.

FIG. 24 is a cross-sectional view schematically showing a step subsequent to the step of FIG. 23 in the graphene nanoribbon fabrication in Embodiment 3.

### DETAILED DESCRIPTION OF THE INVENTION

A first aspect of the present disclosure provides a method for producing a graphene nanoribbon, the method including the steps of forming a crystalline catalytic metal layer composed of copper or nickel on a (110) plane or a (112) plane of a MgAl₂O₄ single-crystal substrate or a MgO single-crystal substrate, with a thickness of the crystalline catalytic metal layer being controlled and with a crystal orientation of the crystalline catalytic metal layer being controlled so that the crystal orientation coincides with a crystal orientation of the single-crystal substrate; forming a cap layer composed of an oxide on the formed catalytic metal layer; exposing a {111} plane of the crystalline catalytic metal layer as a side wall by etching a stack including the substrate, the catalytic metal layer, and the cap layer; and growing graphene selectively on the exposed side wall by chemical vapor deposition.

A second aspect of the present disclosure provides a method for producing a graphene nanoribbon, the method including the steps of: forming a crystalline catalytic metal layer composed of copper or nickel on a (110) plane or a (112) plane of a MgAl₂O₄ single-crystal substrate or a MgO single-crystal substrate, with a thickness of the crystalline catalytic metal layer being controlled and with a crystal orientation of the crystalline catalytic metal layer being controlled so that the crystal orientation coincides with a crystal orientation of the single-crystal substrate; forming at least one pair of a crystalline spacer layer composed of MgAl₂O₄ and an additional crystalline catalytic metal layer that are stacked in this order on the formed catalytic metal layer, with control of a crystal orientation of the spacer layer, a thickness of the additional catalytic metal layer, and a crystal orientation of the additional catalytic metal layer; forming a cap layer composed of an oxide on a stack including the substrate, the catalytic metal layer, the spacer layer, and the additional catalytic metal layer; exposing a (111) plane of at least one layer selected from the catalytic metal layer and the additional catalytic metal layer as a side wall by etching the stack; and growing graphene selectively on the exposed side wall by chemical vapor deposition. The control of the crystal orientations of the spacer layer and the additional catalytic metal layer is carried out so that the crystal orientation of the spacer layer coincides with the crystal orientation of the catalytic metal layer underlying said spacer layer, and that the crystal orientation of the additional catalytic metal layer coincides with the crystal orientation of the spacer layer underlying said additional catalytic metal layer.

A third aspect of the present disclosure provides a method for producing a graphene nanoribbon, the method including the steps of forming a layer composed of copper or nickel on a (110) plane or a (112) plane of a MgAl₂O₄ single-crystal substrate or a MgO single-crystal substrate, with a thickness of the layer being controlled and with a crystal orientation of the layer being controlled so that the crystal orientation coincides with a crystal orientation of the single-crystal substrate; forming a cap layer composed of an oxide on the formed layer composed of copper or nickel; exposing a {111} plane of the layer composed of copper or nickel as a side wall by etching a side surface of the layer; and growing graphene selectively on the exposed side wall.

A fourth aspect of the present disclosure provides a method for producing a graphene nanoribbon, the method including the steps of: forming a layer composed of copper or nickel on a (110) plane or a (112) plane of a MgAl₂O₄ single-crystal substrate or a MgO single-crystal substrate, with a thickness of the layer being controlled and with a crystal orientation of the layer being controlled so that the crystal orientation coincides with a crystal orientation of the single-crystal substrate; forming, on the formed layer composed of copper or nickel, at least one pair of a MgAl₂O₄ single-crystal layer and a layer composed of copper or nickel that are stacked in this order; forming a cap layer composed of an oxide on a stack including the substrate, the layer composed of copper or nickel, and the MgAl₂O₄ single-crystal layer; exposing a {111} plane of the layer composed of copper or nickel as a side wall by etching a side surface of the layer; and growing graphene selectively on the exposed side wall.

A fifth aspect of the present disclosure provides a method for producing a graphene nanoribbon, the method including the steps of: preparing a stack including: a MgAl₂O₄ single-crystal substrate or a MgO single-crystal substrate; and a layer formed on the substrate and composed of copper or nickel, the stack including a {111} plane as a plane perpendicular to a principal surface of the layer; exposing a {111} plane of the layer composed of copper or nickel as a side wall; and growing graphene on the exposed side wall.

A sixth aspect of the present disclosure provides a method for producing a transistor, the method including the step of forming a transistor using the graphene nanoribbon obtained by the production method according to any one of the first to fifth aspects as a channel.

According to embodiments of the present disclosure, a graphene nanoribbon having a controlled width (length in a direction in the plane of the ribbon and perpendicular to a direction in which the graphene ribbon extends; the same applies hereinafter) and having an edge portion with a controlled structure can be formed at a desired position on a substrate. According to the embodiments of the present disclosure, graphene is grown selectively on an exposed side wall of a crystalline catalytic metal layer. Therefore, the thickness of the catalytic metal layer corresponds to the width of the graphene nanoribbon formed. By controlling the thickness of the catalytic metal layer, the width of the graphene nanoribbon can be adjusted to, for example, 15 nm or less, or even 10 nm or less. In this case, the ribbon has a band gap that is sufficiently large for use in a semiconductor device such as a transistor. The smallest possible value of the width of the graphene nanoribbon is a limit value for a technique used for depositing a catalytic metal layer. In addition, the feature of allowing control of the structure of the edge portion of the graphene nanoribbon is particularly advantageous to construction of an electronic device utilizing electrical conduction, such as a transistor. The feature of allowing control of the width of the ribbon, and the feature of allowing formation of the ribbon at a desired position on a substrate, also make an effective contribution to construction of such devices.

Conventional techniques cannot provide these advantageous features. In the case of a method in which graphene is processed using photolithography or electron beam lithography, the smallest possible width of a graphene ribbon to be formed is limited to a level that can be achieved within the limitations of the lithography techniques or the limitations of etching process techniques. The existing techniques can only achieve, at best, an average width larger than 15 nm. Furthermore, it has been pointed out that, at such a fine-scale, the achievable uniformity of the width is poor. Therefore, a band gap of 0.2 eV or more cannot be achieved. In addition, the structure of the edge portion of a graphene ribbon formed by this conventional method lacks linearity due to the limitations of the spatial resolution of lithography techniques and etching process techniques, and is composed of randomly-mixed zigzag type and armchair type structures. A graphene nanoribbon having an edge portion with such a structure does not have stable properties, and is difficult to apply to an electronic device.

In the case of a method in which carbon nanotubes are cut open and processed into ribbons, graphene nanoribbons are formed in a state of being diffused in a solvent. In order to apply the formed ribbon to an electronic device, the ribbon needs to be selectively taken out from the solvent, and disposed at a predetermined position on a substrate. In fact, however, such operations are very difficult to carry out. In addition, the formation of graphene nanoribbon in this method is probabilistic. Therefore, an unprocessed carbon nanotube, graphene fragments in other forms than ribbon, and graphene fragments being in the form of ribbon but not having a desired width, are also present in large amounts in the solvent. There is no technique for selectively separating desired graphene nanoribbons from these materials. In addition, hundreds of millions of transistors are incorporated in a state-of-the-art integrated circuit. Even when desired graphene nanoribbons can be selectively separated, none of the existing arrangement techniques allow the graphene nanoribbons to be appropriately arranged on all of the transistors formed on a substrate and to appropriately function. That is, graphene nanoribbons fabricated by the conventional methods are practically impossible to apply to elements, electronic devices, and integrated circuits. In addition, it is known that a carbon nanotube is easily cut open along a certain direction and thus a particular type of structure tends to be formed in the edge portion of a graphene nanoribbon. Therefore, with this method, the structure of the edge portion of a graphene nanoribbon cannot be formed selectively into a zigzag type structure or an armchair type structure.

WO 2011/025045 A1 nowhere discloses a method for producing a graphene nanoribbon.

In contrast, according to one embodiment of the present disclosure, a graphene nanoribbon having a controlled width and having an edge portion with a controlled structure is formed based on a metal layer deposition technique that allows more accurate, finer-scale thickness control than lithography and etching which are techniques for process in a plane direction, and based on a metal layer crystal orientation control technique.

The additional catalytic metal layer means a second or subsequent catalytic metal layer when two or more catalytic metal layers are formed on a substrate. All the catalytic metal layers are composed of catalytic metal.

The selective growth of graphene (selective graphene growth) means a process in which graphene grows on a side wall of the catalytic metal layer but not on side walls of the substrate, the spacer layer, and the cap layer.

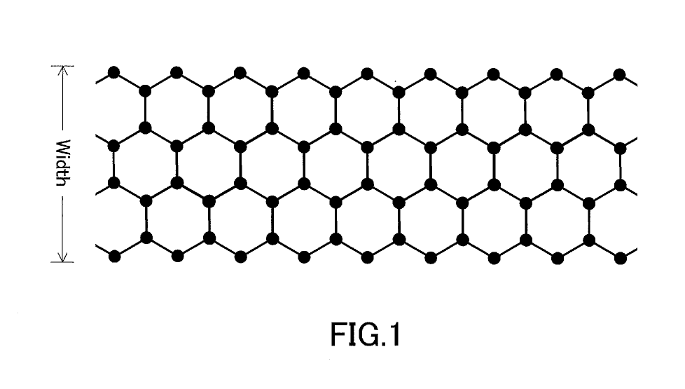

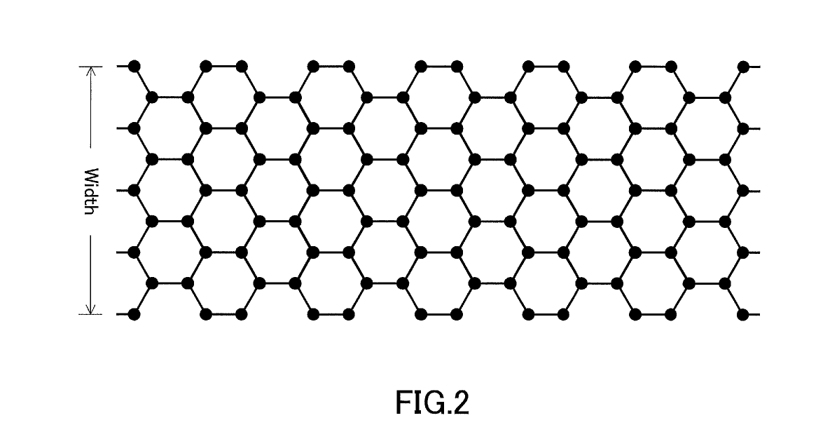

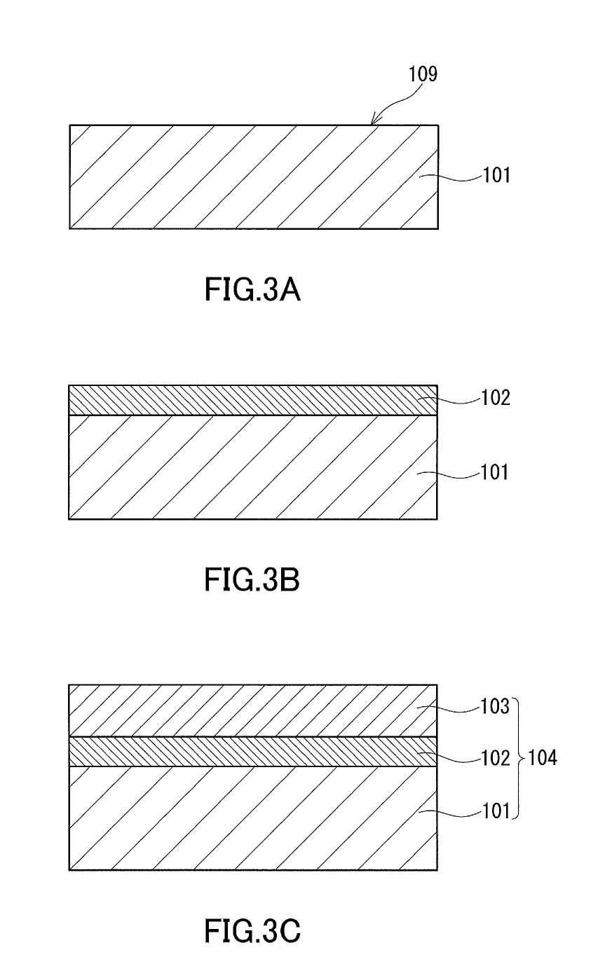

Hereinafter, specific embodiments will be described with reference to the drawings. In the present specification, the same components shown in FIG. 3A and the subsequent figures are denoted by the same reference numerals, and redundant descriptions may be omitted. All of the figures including FIGS. 1 and 2 are schematic conceptual diagrams for illustrating embodiments of the present disclosure. Therefore, the figures are not necessarily drawn in such a manner that the reduction scale, the visual size ratio between the components, and the like, represent exactly the actual structure.

### Embodiment 1

Embodiment 1 is a method for producing a graphene nanoribbon. FIGS. 3A to 6 are diagrams for illustrating the steps of Embodiment 1.

### Step 1a

### Preparation of Crystalline Substrate

First, as shown in FIG. 3A, a crystalline substrate 101 on which a catalytic metal layer is to be formed is prepared. The crystalline substrate 101 has a surface 109 on which a catalytic metal layer is to be deposited or grown.

The type of the crystalline substrate 101 is selected as follows depending on the type of the graphene nanoribbon intended to be fabricated. In the case where a graphene nanoribbon having an edge portion with a zigzag type structure is produced, a spinel (MgAl₂O₄) single-crystal substrate whose surface 109 is a (112) plane, or a MgO single-crystal substrate whose surface 109 is a (112) plane, is selected. In the case where a graphene nanoribbon having an edge portion with an armchair type structure is produced, a spinel (MgAl₂O₄) single-crystal substrate whose surface 109 is a (110) plane, or a MgO single-crystal substrate whose surface 109 is a (110) plane, is selected.

A MgAl₂O₄ substrate and a MgO substrate are characterized by having a surface on which graphene is less likely to grow in a selective graphene growth step (step 8a) described later.

A MgAl₂O₄ single-crystal substrate that can be used in Embodiment 1 is a substrate composed of a spinel single crystal in which Mg atoms and Al atoms are arranged between oxygen atoms. The oxygen atoms form a basic skeleton of the face-centered cubic type. This single-crystal substrate has a (111) plane. A {111} plane is a concept including a (111) plane and a plane equivalent to the (111) plane, and is orthogonal to the (110) plane or the (112) plane, that is, the surface 109. In general, spinel is a material that has a composition represented by a formula XY₂O₄ (X is Mg, Fe, or Mn, and Y is Al, Fe, or Cr) and that has a spinel type crystal structure. In Embodiment 1, spinel in which Mg and Al are selected as X and Y respectively is employed. Spinel has no deliquescent properties, and is thus more stable than MgO. For example, a MgAl₂O₄ single-crystal substrate grown by CZ process (Czochralski process) is available.

At least a part of the entire surface of the crystalline substrate 101 is the surface 109 on which a catalytic metal layer is to be deposited or grown. Therefore, the crystalline substrate 101 can be a thin film formed on another substrate. In addition, another functional device, component, or structure, such as a transistor, a capacitor, or a isolation trench, may be formed or disposed in a portion of the substrate 101 other than the portion where a catalytic metal layer is to be deposited or grown.

The crystalline substrate 101 may have an indicator (not shown) that allows identification of the {111} plane direction of the substrate 101. As the indicator, an orientation flat or a notch used in a general semiconductor process can be employed.

### Step 2a

### Formation of Crystalline Catalytic Metal Layer

Next, a crystalline catalytic metal layer is formed on the surface 109 of the crystalline substrate 101, with the thickness and crystal orientation of the layer being controlled. The control of the crystal orientation is carried out so that the crystal orientation of the catalytic metal layer to be formed coincides with the crystal orientation of the crystalline substrate 101.

Two methods are presented below as examples of the method for forming the crystalline catalytic metal layer.

The first method is to deposit a catalytic metal layer without a guarantee of crystallinity, and to crystallize the catalytic metal layer by the subsequent crystallization treatment. The second method is to grow a crystalline catalytic metal layer directly on the surface 109 of the crystalline substrate 101.

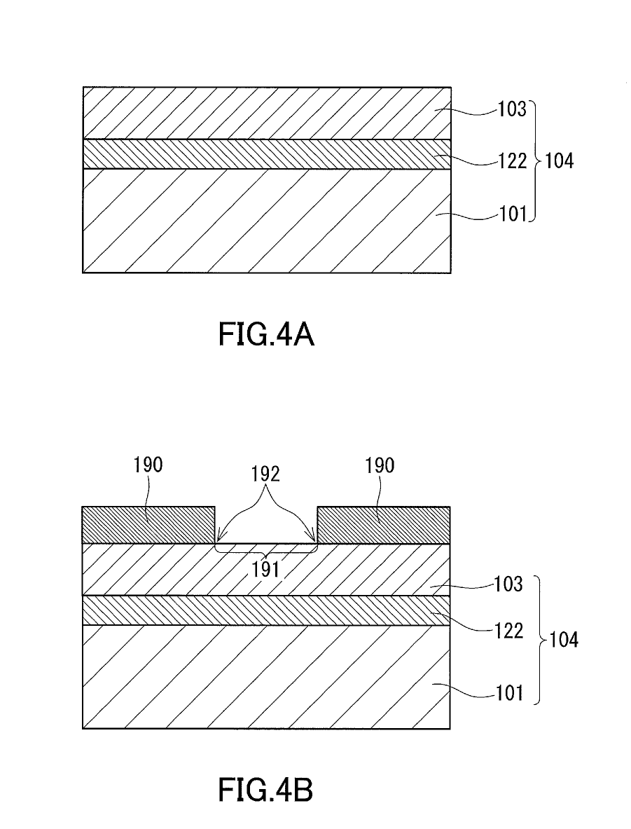

FIG. 3B to FIG. 4A show the first method. First, a catalytic metal layer 102 composed of a catalytic metal is deposited on the crystalline substrate 101 (FIG. 3B). Next, a cap layer 103 is formed on the deposited catalytic metal layer 102 (FIG. 3C). Next, the catalytic metal layer 102 is crystallized and converted into a crystalline catalytic metal layer 122 (FIG. 4A). The order of the formation of the cap layer (step 3a described later) and the crystallization of the catalytic metal layer 102 may be reversed. When the second method is selected, the crystalline catalytic metal layer 122 is formed directly on the crystalline substrate 101, and the crystallization of the catalytic metal layer 102 is omitted.

In either method, it is desirable that the surface 109 used for formation of a crystalline catalytic metal layer on the substrate 101 be previously cleaned to remove an impurity from the surface. For the impurity removal, a treatment method used in a general crystal growth process can be employed. For example, when the impurity is an organic substance, cleaning with a liquid such as acetone or decomposition treatment with an UV ozonizer can be employed. An appropriate treatment method is selected depending on the type of the impurity. When a liquid is used for the impurity removal, it is desirable that the surface 109 be sufficiently dried using dry nitrogen or the like before the catalytic metal layer is deposited or grown.

The material composing the catalytic metal layer 102 and the crystalline catalytic metal layer 122 is selected from copper and nickel.

For example, a sputtering method, a molecular beam epitaxy (MBE) method, and an electron beam evaporation method can be employed for the deposition of the catalytic metal layer 102 in the first method and for the growth of the crystalline catalytic metal layer 122 in the second method.

The crystallization of the catalytic metal layer 102 in the case of the first method will be separately described later as a step 4a.

In either method, a catalytic metal is deposited on the surface 109 of the substrate 101. The difference between the first method and the second method lies in the conditions for the deposition of the catalytic metal. When a sufficient thermal energy is imparted during the deposition of the catalytic metal and the deposition rate is low, the catalytic metal is deposited in the form of a crystal (a crystalline catalytic metal layer grows). On the other hand, when a sufficient thermal energy is not imparted or when the deposition rate is too high, crystallization does not proceed sufficiently, as a result of which an amorphous or polycrystalline layer is formed. Whether or not the crystallization has proceeded sufficiently can be evaluated by X-ray diffraction or electron beam diffraction. When those who carry out the invention select the second method, it is desirable to previously confirm, using a condition-setting sample or the like, whether or not the crystallization of the catalytic metal proceeds sufficiently under the deposition conditions set by themselves. When an insufficiently-crystallized catalytic metal layer is formed despite the second method being selected, the method used may be switched to the first method, and the crystallization of the step 4a may be carried out.

When the first method is selected, the catalytic metal layer 102 having no guarantee of crystallinity is formed.

When the second method is selected, and combination of copper or nickel with spinel (MgAl₂O₄) or MgO is employed, the crystalline catalytic metal layer 122 grows in such a manner that its crystal orientation coincides with the crystal orientation of the crystalline substrate 101.

When the surface 109 of the substrate 101 is a (110) plane, (the crystal of) the crystalline catalytic metal layer 122 grows in such a manner that the surface of the layer 122 parallel to the principal surface of the substrate is a (110) plane. On the other hand, when the surface 109 of the substrate 101 is a (112) plane, (the crystal of) the crystalline catalytic metal layer 122 grows in such a manner that the surface of the layer 122 parallel to the principal surface of the substrate is a (112) plane.

The (110) plane and the (112) plane are perpendicular to a {111} plane that includes a (111) plane and a plane equivalent to the (111) plane. When the second method is selected, the crystalline catalytic metal layer 122 formed has a {111} plane that extends perpendicularly to the surface 109 used for the growth of the catalytic metal (the principal surface of the substrate 101 in the example shown in FIG. 3A).

In either the first method or the second method, the thickness at which the catalytic metal is deposited (the thickness of the catalytic metal layer 102 or 122) is made equal to the width of the graphene nanoribbon intended to be fabricated. The width of the graphene nanoribbon can be arbitrarily selected depending on the purpose of the ribbon.

The thickness can be controlled, for example, by the deposition time. For example, the deposition rate is previously calculated from the relationship between the thickness of the layer formed and the deposition time, and the deposition time is controlled so that an intended thickness can be obtained.

In the case of a sputtering method, a MBE method, or an electron beam evaporation method, the apparatus for carrying out the method is usually provided with a shutter, and the deposition time can be controlled by opening and closing the shutter. The time from opening to closing in a general shutter is 1 second or less. Therefore, when the deposition rate is 1 nm/second or less, the thickness of the catalytic metal can be controlled to a precision of 1 nm.

For example, in the experimental environment of the present inventors, when the catalytic metal was copper or nickel, a deposition rate of 0.15 nm/second was achieved by setting the distance between the target and the substrate to several tens of centimeters under the conditions that the process pressure was 1 Pa, the plasma output was 100 W, and the substrate temperature was 500° C. In this case, the shutter may be opened for 67 seconds in order to deposit a catalytic metal with a thickness of 10 nm. As a matter of course, a catalytic metal with a thickness of 10 nm or less can be deposited by shortening the shutter opening time.

### Step 3a

### Deposition of Cap Layer

Next, the cap layer 103 is deposited on the formed catalytic metal layer 102 or 122. In the example shown in FIG. 3C, the first method is selected in the step 2a. Therefore, the cap layer 103 is deposited on the catalytic metal layer 102.

The material composing the cap layer 103 has the feature that graphene is less likely to grow on the surface of the cap layer 103 in the selective graphene growth step (step 8a) described later. Examples of materials that possess this feature include oxides such as silicon dioxide, aluminum oxide, and spinel.

The cap layer 103 can take any of single-crystalline form, polycrystalline form, and amorphous form. Examples of the method for forming the cap layer include a sputtering method, an electron beam evaporation method, a MBE method, a chemical vapor deposition (CVD) method, and a spin coating method. In one example, an apparatus used for carrying out the deposition of the catalytic metal in the step 2a can be continuously used for formation of the cap layer by changing the target. As a matter of course, different apparatuses can be used in the steps 2a and 3a. The layer formation method can be changed between the steps 2a and 3a.

The thickness of the cap layer 103 to be formed can be arbitrarily selected.

As a result of the formation of the cap layer 103, a stack (layered structure) 104 of the crystalline substrate 101, the catalytic metal layer 102 or 122, and the cap layer 103 is formed.

### Step 4a

### Crystallization

When the first method is selected in the step 2a, the catalytic metal layer 102 is subsequently crystallized to form the crystalline catalytic metal layer 122 (FIG. 4A). When the second method is selected in the step 2a, the step 4a can be omitted.

The crystallization of the catalytic metal layer 102 can be carried out, for example, by heating treatment.

The time required for the crystallization depends on the heating temperature, the type of the catalytic metal, the thickness of the catalytic metal deposited in the step 2a, and the state of the catalytic metal layer 102 yet to be crystallized. Whether or not sufficient crystallization has taken place can be evaluated by X-ray diffraction or electron backscatter diffraction (EBSD). The treatment time can be, for example, a necessary treatment time previously determined using a condition-setting sample.

Exemplary specific process conditions are such that heating is performed in a hydrogen atmosphere of ordinary pressure at 1050° C. for 20 minutes. With the process conditions, single crystallization of copper having a thickness of 10 nm can be achieved.

Basically, the heating atmosphere is desirably a reducing or inert atmosphere in order to prevent oxidation of the catalytic metal layer 102. Examples of the reducing atmosphere include a hydrogen atmosphere, and a mixed atmosphere of hydrogen and argon or helium. Examples of the inert atmosphere include an argon atmosphere and a helium atmosphere. In the case where oxidation of the catalytic metal layer 102 can be suppressed by the presence of the cap layer 103, an oxidizing atmosphere or a nitriding atmosphere can be selected.

The catalytic metal layer 102 is converted into the crystalline catalytic metal layer 122 by the heating treatment.

In the case of a combination of copper or nickel with spinel (MgAl₂O₄) or MgO, the crystal orientation of the resultant crystalline catalytic metal layer 122 coincides with the crystal orientation of the crystalline substrate 101. That is, when a (110) plane is selected as the surface 109 of the substrate 101, the surface of the catalytic metal layer 122 that is parallel to the principal surface of the substrate 101 is a (110) plane. When a (112) plane is selected as the surface 109 of the substrate 101, the surface of the catalytic metal layer 122 that is parallel to the principal surface of the substrate 101 is a (112) plane.

The (110) plane and the (112) plane are perpendicular to a {111} plane. Through the steps described thus far, the crystalline catalytic metal layer 122 having a {111} plane that extends perpendicularly to the surface 109 of the substrate 101 is obtained.

### Step 5a

### Formation of Etching Mask

Next, an etching mask 190 is formed on the layered structure 104 (FIG. 4B). For formation of the mask 190, a photolithography technique generally used in a conventional semiconductor mass-production process can be employed. Electron beam lithography can be employed as necessary.

A mask pattern is selected in such a manner that, in the portion of the layered structure 104 where a graphene nanoribbon is intended to be formed, a boundary 191 between the mask 190 and a region 192 not covered with the mask 190 is parallel to the {111} plane of the catalytic metal layer 122.

In the case of a combination of copper or nickel with spinel (MgAl₂O₄) or MgO, the crystal orientation of the crystallized catalytic metal coincides with the crystal orientation of the crystalline substrate. That is, the {111} plane of the crystalline catalytic metal layer 122 is parallel to the {111} plane of the crystalline substrate 101. Therefore, the indicator prepared in the step 1a to allow identification of the {111} plane direction of the substrate 101 can be used for formation of the mask 190. For example, the {111} plane direction of the catalytic metal layer 122 is determined using this indicator, and then the mask 190 is formed.

The entire mask pattern boundary 191 need not be parallel to the {111} plane. The mask 190 is formed in such a manner that the boundary 191 in the portion where a graphene nanoribbon is intended to be fabricated is parallel to the {111} plane.

### Step 6a

### Etching

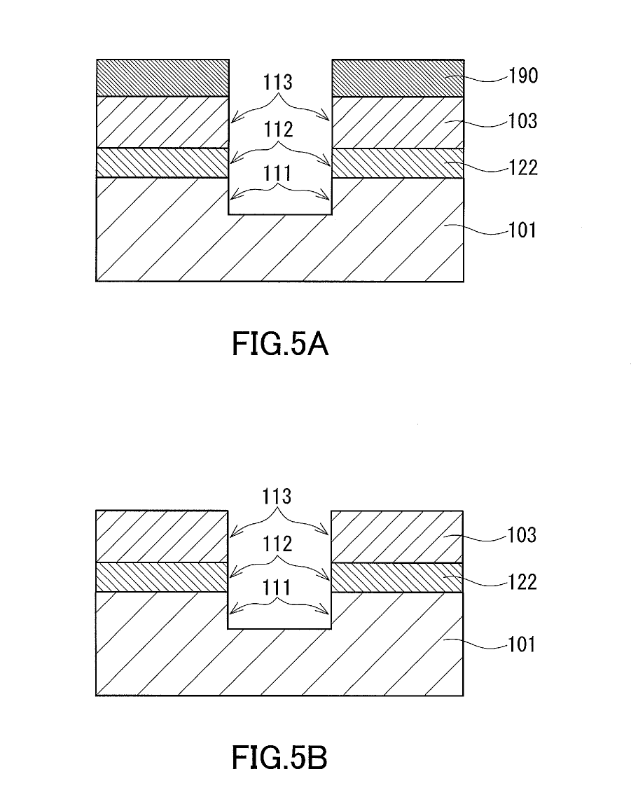

Next, etching process is performed to expose the {111} plane of the crystalline catalytic metal layer 122 as a side wall 112 (FIG. 5A). The {111} plane of the catalytic metal layer 122 lies perpendicular to the surface 109 used for the growth of the catalytic metal. Therefore, the {111} plane of the catalytic metal layer 122 can be exposed as the side wall 112 by carrying out etching in the direction perpendicular to the surface 109 using the mask 190 fabricated in the step 5a.

The etching is carried out up to at least the boundary between the substrate 101 and the catalytic metal layer 122 in the layered structure 104. The substrate 101 may be etched so as to be fully penetrated, may be partially etched, or may not be etched at all. The method for the etching is, for example, dry etching or ion milling.

For example, in order to complete etching up to the boundary between the substrate 101 and the catalytic metal layer 122, management of the etching time is carried out. Specifically, the rates of etching of the cap layer 103 and the catalytic metal layer 122 are previously measured using condition-setting samples, a necessary time is calculated from the measured rates, and the etching time is managed based on the calculated time. Alternatively, whether etching has been completed up to the interface between the substrate 101 and the catalytic metal layer 122 may be confirmed by placing an elemental analyzer in an etching apparatus and detecting an element contained not in the catalytic metal layer 122 but in the substrate 101.

### Step 7a

### Annealing Treatment and Surface Reduction Treatment

Next, the mask 190 is removed, and then an annealing treatment and a surface reduction treatment of the side wall 112 of the catalytic metal layer 122 are performed to carry out crystallinity restoration and surface reduction (FIG. 5B). These two treatments can be simultaneously carried out by a thermal treatment in a reducing atmosphere.

The annealing treatment and the surface reduction treatment are desirably carried out in the same apparatus as used for the selective graphene growth step (step 8a) described later, in order to avoid reoxidation after the treatments. However, the same apparatus need not be used in the steps 7a and 8a. An apparatus coupled to an apparatus for carrying out the step 8a may be used to carry out the step 7a, or an apparatus having a controlled internal atmosphere and configured to convey the stack 104 from the apparatus for the step 7a to the apparatus for the step 8a may be used.

The reducing atmosphere is, for example, a hydrogen atmosphere or a mixed atmosphere of hydrogen and inert gas such as argon.

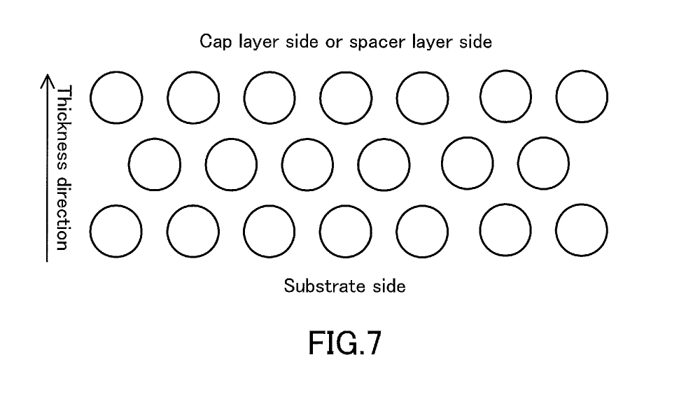

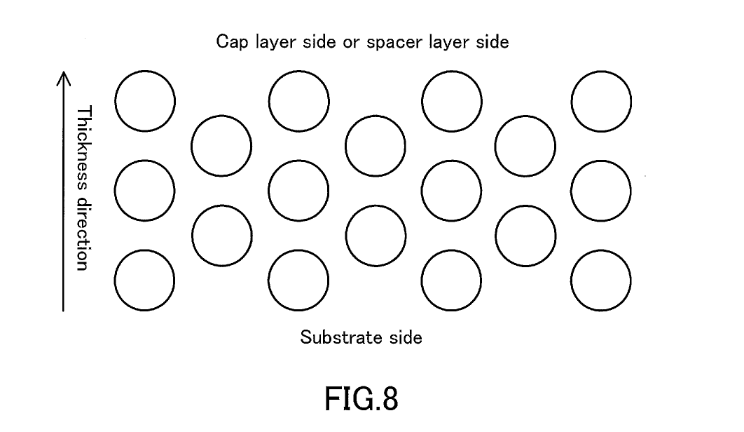

FIGS. 7 and 8 show examples of the atomic arrangement in the side wall 112 having been subjected to the annealing treatment and the surface reduction treatment. FIG. 7 shows an example in the case where a (112) plane is selected as the surface 109 used for the growth of the catalytic metal. FIG. 8 shows an example in the case where a (110) plane is selected as the surface 109 used for the growth of the catalytic metal.

The temperature and time required for the step 7a vary depending on the materials composing the layers, the conditions for the etching process, and how the layered structure 104 is stored from the etching step to the present step. The temperature and time required for allowing the step 7a to proceed sufficiently may be previously determined using a condition-setting sample, and the step 7a may be allowed to proceed under the determined conditions. In the case where oxidation and disordered atomic arrangement caused by the etching are insufficiently resolved, a graphene nanoribbon does not normally grow on the side wall 112. Therefore, the examination of the conditions may be made based on whether the graphene nanoribbon normally grows. Exemplary conditions are such that a thermal treatment is performed in a hydrogen atmosphere of ordinary pressure at 1050° C. for 20 minutes. With this treatment, the crystallinity of copper is restored, and surface reduction is carried out.

### Step 8a

### Selective Graphene Growth

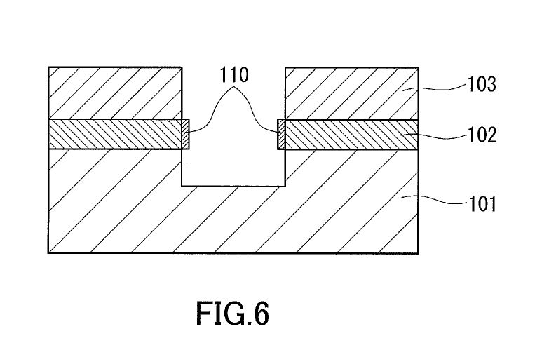

Next, a process of selective graphene growth is allowed to proceed, and a graphene nanoribbon 110 is grown on the side wall 112 of the catalytic metal layer 122 (FIG. 6). The selective growth process is a process in which graphene grows on the side wall 112 of the crystalline catalytic metal layer 122, but does not grow on a side wall 111 of the crystalline substrate 101 or a side wall 113 of the cap layer 103.

The selective growth process can be carried out by a chemical vapor deposition (CVD) method. The CVD method is a method in which a source material is fed in the form of molecules, and growth by chemical reaction with the substrate is allowed to proceed. Since the source material is in the form of molecules, graphene grows only on a surface having a function as a catalyst for decomposing the molecules.

The side wall 112 of the crystalline catalytic metal layer 122 has a catalytic function for graphene growth derived from copper or nickel. On the other hand, the side wall 111 of the crystalline substrate 101 and the side wall 113 of the cap layer 103 are oxidized, and have no catalytic function for graphene growth. Therefore, a graphene nanoribbon can be selectively grown only on the side wall 112.

The graphene growth by CVD can be carried out as follows: the substrate 101 (stack 104) is heated in an atmosphere containing a source gas such as methane or ethylene, with the side wall 112 of the catalytic metal layer 122 being exposed, and the substrate 101 (stack 104) is then cooled. The appropriate substrate temperature varies depending on the type of the catalytic metal and the type of the source gas. Nickel has a higher ability to decompose hydrocarbons than copper. Therefore, when a highly-decomposable source gas is used or when the process is allowed to proceed at a high temperature, selective growth of graphene is less likely to be achieved. In the case of nickel, it is appropriate that, for example, a mixed gas of 1 volume % methane and 99 volume % hydrogen be used as the source gas, and the process temperature be set to around 850° C. On the other hand, in the case of copper having a lower ability to decompose hydrocarbons than nickel, it is appropriate that, for example, hydrogen-diluted ethylene that is highly decomposable (the ethylene concentration is about 100 ppm to 1 volume %) be used as the source gas, the process temperature be set to around 1050° C., and the process time be set to about 1 minute to 20 minutes. These conditions are illustrative examples, and other conditions can be employed as long as the selectivity of graphene growth can be achieved.

By this step 8a, the graphene nanoribbon 110 is formed only on the surface of the side wall 112 of the crystalline catalytic metal layer 122 in the stack 104. The structure of the edge portion of the grown graphene nanoribbon reflects the atomic arrangement in the surface of the side wall 112.

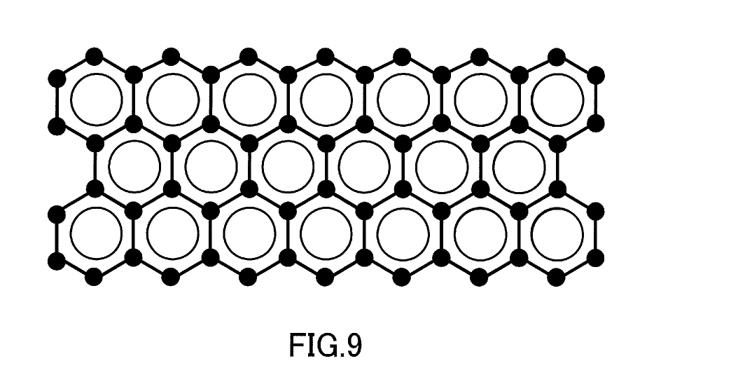

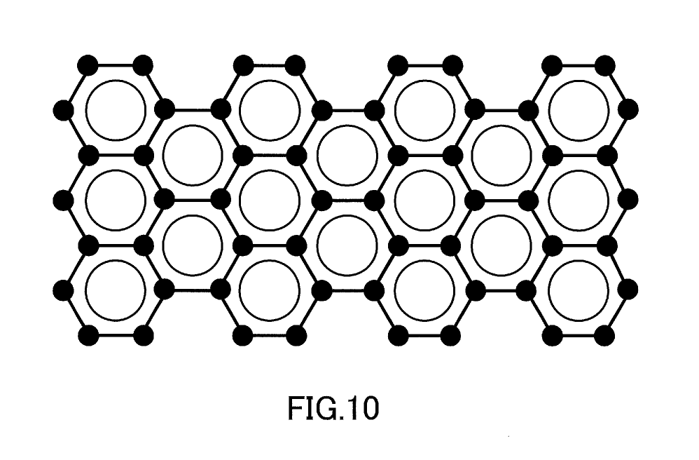

In the case of the atomic arrangement of FIG. 7, a graphene nanoribbon having an edge portion with a structure shown in FIG. 9 grows, that is, a graphene nanoribbon having an edge portion with a zigzag type structure grows. In the case of the atomic arrangement of FIG. 8, a graphene nanoribbon having an edge portion with a structure shown in FIG. 10 grows, that is, a graphene nanoribbon having an edge portion with an armchair type structure grows.

As described for the step 6a, the atomic arrangement in the surface of the side wall 112 is determined by selection of the surface 109 in the step 1a. The atomic arrangement of FIG. 7 is an atomic arrangement in the surface of the side wall 112 in the case where a (112) plane is selected as the surface 109. In this case, a graphene nanoribbon having an edge portion with a zigzag type structure shown in FIG. 9 grows. The atomic arrangement of FIG. 8 is an atomic arrangement in the surface of the side wall 112 in the case where a (110) plane is selected as the surface 109. In this case, a graphene nanoribbon having an edge portion with an armchair type structure shown in FIG. 10 grows. Thus, with the production method of the present disclosure, a graphene nanoribbon having an edge portion with a controlled structure can be produced by selection of the surface 109 used for growth of a catalytic metal.

The width of the graphene nanoribbon 110 is equal to the exposed width of the side wall 112 of the catalytic metal layer 122. The width is equal to the thickness of the catalytic metal layer 120 or 122. The thickness of the catalytic metal layer 102 or 122 can easily be adjusted to 10 nm or less by the existing semiconductor technology. Therefore, with the production method of the present disclosure, a graphene nanoribbon having a width of 10 nm or less can be produced.

In the production method of the present disclosure, the position of the side wall 112 on which the graphene nanoribbon 110 grows can be determined in the process for exposing the side wall by etching. Therefore, the graphene nanoribbon 110 can be formed at a desired position on the substrate. That is, with the production method of the present disclosure, a graphene nanoribbon having an edge portion with a controlled structure and having a desired width can be formed at a desired position on the substrate.

### EXAMPLES

The examples presented below describe the present invention in more detail. The method of the present disclosure is not limited to the examples presented below.

In the present examples, the crystalline states of catalytic metal layers formed on substrates were evaluated by varying the materials of the substrates, the plane directions of surfaces used for growth of catalytic metals on the substrates, and the types of the catalytic metals.

Table 1 shows the materials of the substrates used, the plane directions of the surfaces of the substrates used for growth of catalytic metals (simply described as “Plane direction” in Table 1), the types of the catalytic metals, and the crystalline states of the catalytic metal layers formed. The spinel (MgAl₂O₄), MgO, and sapphire shown in “Material of substrate” of Table 1 were all single crystals.

TABLE 1

| | | | Material of | |
|---|---|---|---|---|
| | Material of | Plane | catalytic | Result of crystal |
| | substrate | direction | metal | growth |
| Example 1 | Spinel | (110) | Nickel | Single crystal |
| | (MgAl₂O₄) | | | having a (110) |
| | | | | plane parallel to |
| | | | | the substrate |
| Example 2 | Spinel | (110) | Copper | Single crystal |
| | (MgAl₂O₄) | | | having a (110) |
| | | | | plane parallel to |
| | | | | the substrate |
| Example 3 | Spinel | (112) | Nickel | Single crystal |
| | (MgAl₂O₄) | | | having a (112) |
| | | | | plane parallel to |
| | | | | the substrate |
| Example 4 | Spinel | (112) | Copper | Single crystal |
| | (MgAl₂O₄) | | | having a (112) |
| | | | | plane parallel to |
| | | | | the substrate |
| Example 5 | MgO | (110) | Nickel | Single crystal |
| | | | | having a (110) |
| | | | | plane parallel to |
| | | | | the substrate |
| Example 6 | MgO | (110) | Copper | Single crystal |
| | | | | having a (110) |
| | | | | plane parallel to |
| | | | | the substrate |
| Example 7 | MgO | (112) | Nickel | Single crystal |
| | | | | having a (112) |
| | | | | plane parallel to |
| | | | | the substrate |
| Example 8 | MgO | (112) | Copper | Single crystal |
| | | | | having a (112) |
| | | | | plane parallel to |
| | | | | the substrate |
| Comparative | Sapphire | c plane | Nickel | Bicrystal having |
| Example 1 | | | | a (111) plane |
| | | | | parallel to the |
| | | | | substrate |
| Comparative | Sapphire | c plane | Copper | Bicrystal having |
| Example 2 | | | | a (111) plane |
| | | | | parallel to the |
| | | | | substrate |
| Comparative | Sapphire | a plane | Nickel | Single crystal |
| Example 3 | | | | having a (001) |
| | | | | plane parallel to |
| | | | | the substrate |
| Comparative | Sapphire | a plane | Copper | Single crystal |
| Example 4 | | | | having a (001) |
| | | | | plane parallel to |
| | | | | the substrate |
| Comparative | Sapphire | r plane | Nickel | Polycrystal |
| Example 5 | | | | |
| Comparative | Sapphire | r plane | Copper | Single crystal |
| Example 6 | | | | having a (111) |
| | | | | plane parallel to |
| | | | | the substrate |
| Comparative | Spinel | (111) | Nickel | Single crystal |
| Example 7 | (MgAl₂O₄) | plane | | having a (111) |
| | | | | plane parallel to |
| | | | | the substrate |
| Comparative | Spinel | (111) | Copper | Single crystal |
| Example 8 | (MgAl₂O₄) | plane | | having a (111) |
| | | | | plane parallel to |
| | | | | the substrate |
| Comparative | MgO | (111) | Nickel | Single crystal |
| Example 9 | | plane | | having a (111) |
| | | | | plane parallel to |
| | | | | the substrate |
| Comparative | MgO | (111) | Copper | Single crystal |
| Example 10 | | plane | | having a (111) |
| | | | | plane parallel to |
| | | | | the substrate |

As shown in Table 1, in each of Examples 1, 2, 5, and 6, a catalytic metal layer composed of a single crystal having a (110) plane parallel to the principal surface of the substrate and a {111} plane perpendicular to the principal surface of the substrate was formed. In each of Examples 3, 4, 7, and 8, a catalytic metal layer composed of a single crystal having a (112) plane parallel to the principal surface of the substrate and a {111} plane perpendicular to the principal surface of the substrate was formed.

On the other hand, in each of Comparative Examples 1 to 6 in which a sapphire single crystal was used for the substrate, a bicrystalline catalytic metal layer having a (111) plane parallel to the principal surface of the substrate, a bicrystalline catalytic metal layer having a (001) plane parallel to the principal surface of the substrate, or a polycrystalline catalytic metal layer, was formed. In the case of such a catalytic metal layer, graphene cannot be grown selectively on the side wall of the layer.

In each of Comparative Examples 7 to 10 in which a spinel (MgAl₂O₄) single crystal or a MgO single crystal was used for the substrate but the plane direction of the surface used for growth of a catalytic metal was (111), a single crystal catalytic metal layer was formed, but the crystal orientation of the layer was such that the (111) plane was located parallel to the principal surface of the substrate. In the case of such a catalytic metal layer, graphene cannot be grown selectively on the side wall of the layer.

The results shown in Table 1 indicate that the following conditions 1 or conditions 2 need to be satisfied in order for graphene to be grown selectively on the side wall of a catalytic metal layer.

Conditions 1: The material of the substrate is MgAl₂O₄ single crystal, the surface of the substrate used for growth of the catalytic metal is a (110) plane or a (112) plane, and the type of the catalytic metal is nickel or copper.

Conditions 2: The material of the substrate is MgO single crystal, the surface of the substrate used for growth of the catalytic metal is a (110) plane or a (112) plane, and the type of the catalytic metal is nickel or copper.

### Embodiment 2

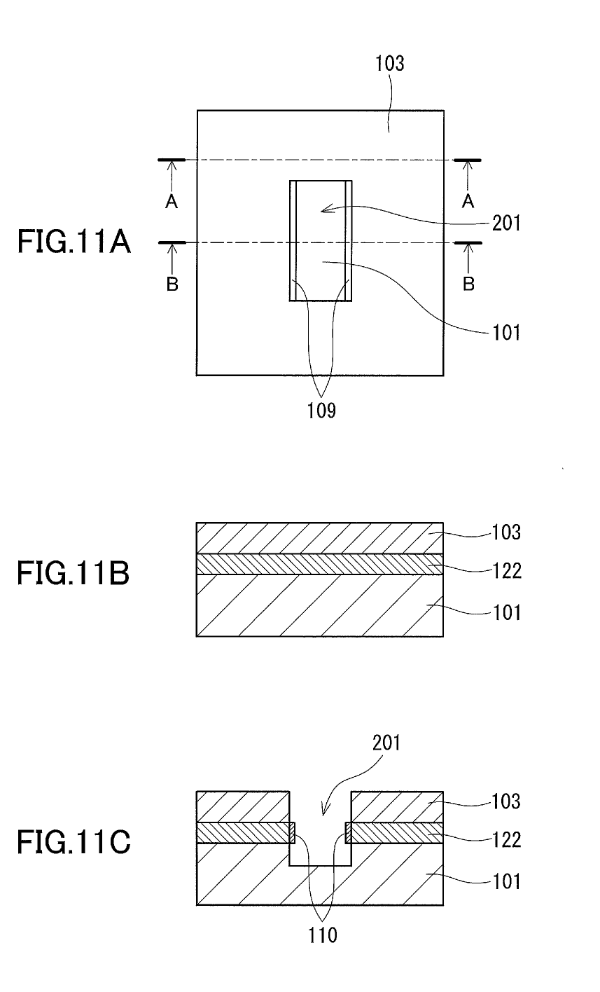

As an example where the graphene nanoribbon fabricated in Embodiment 1 is used, the production steps of a transistor using this graphene nanoribbon will be described with reference to FIG. 11A to FIG. 18D. These figures are schematic diagrams for illustrating the production steps of the transistor, and do not take the reduction scale into account. In addition, components not involved in production of the transistor are omitted from the figures.

The transistor production procedure described in Embodiment 2 is merely an example of using the graphene nanoribbon obtained by the method of the present disclosure. The graphene nanoribbon obtained by the method of the present disclosure can be used for other procedures or other devices.

For the transistor of Embodiment 2, a graphene nanoribbon formed through the step 1a to the step 8a in Embodiment 1 is used. Therefore, the steps subsequent to the step 8a will be described.

### Step 9a

### Deposition of Insulating Film

FIGS. 11A to 11C include a top view of a stack (transistor substrate) in which the graphene nanoribbon 110 has been fabricated through the procedure described in Embodiment 1, and two cross-sectional views of the stack taken along different directions. FIG. 11B shows a cross-section A-A of FIG. 11A, and FIG. 11C shows a cross-section B-B of FIG. 11A. In the transistor substrate, a rectangular hole 201 is formed in the stack of the crystalline substrate 101, the crystalline catalytic metal layer 122, and the cap layer 103, and the graphene nanoribbon 110 is formed on a side wall ({111} plane) of the catalytic metal layer 122 that is exposed to the hole 201.

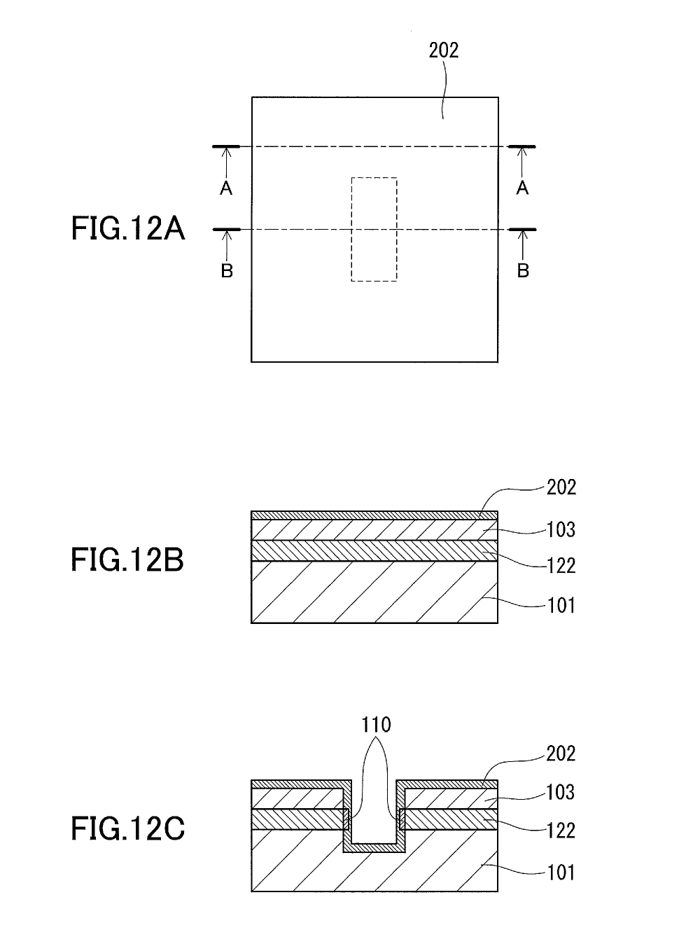

Next, an insulating film 202 is deposited onto the transistor substrate so as to cover at least the graphene nanoribbon 110 (FIGS. 12A to 12C; FIG. 12B shows a cross-section A-A of FIG. 12A, and FIG. 12C shows a cross-section B-B of FIG. 12A). The insulating film 202 is, for example, a silicon oxide film, an alumina film, a spinel (MgAl₂O₄) film, a hafnium oxide film, a silicon nitride film, or a gallium nitride film. Other oxide films or nitride films can be used.

The deposition of the insulating film 202 can be carried out, for example, by a sputtering method, a CVD method, a spin coating method, or an atomic layer deposition (ALD) method.

### Step 10a

### Deposition of Gate Electrode

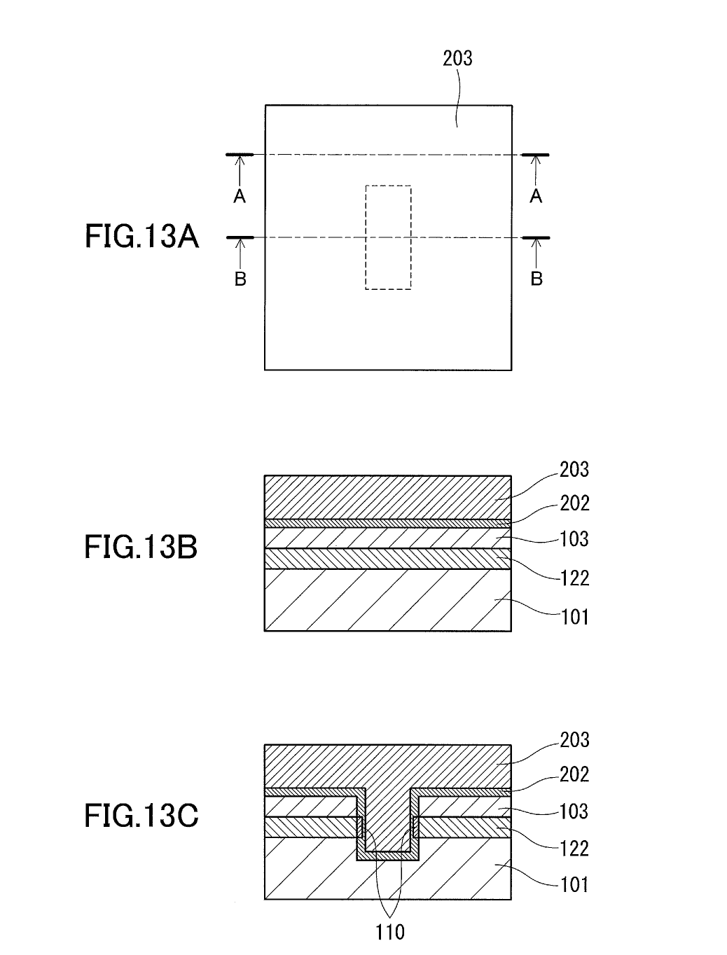

Next, a gate electrode 203 is deposited on the insulating film 202 having been deposited (FIGS. 13A to 13C; FIG. 13B shows a cross-section A-A of FIG. 13A, and FIG. 13C shows a cross-section B-B of FIG. 13A). For example, the gate electrode 203 is composed of a metal such as aluminum, copper, tungsten, nickel or gold, an alloy thereof, or polycrystalline silicon doped with an impurity. The deposition of the gate electrode 203 can be carried out, for example, by a sputtering method, an electron beam evaporation method, a MBE method, or a CVD method.

### Step 11a

### Planarization

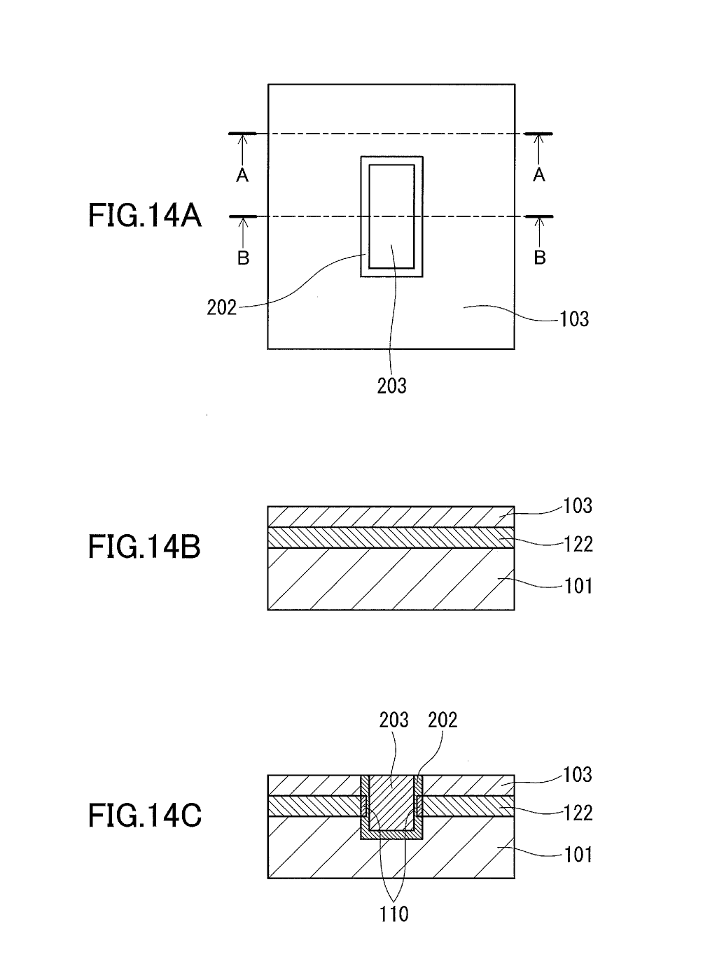

Next, the gate electrode 203 deposited on a region other than the hole 201 is removed (FIGS. 14A to 14C; FIG. 14B shows a cross-section A-A of FIG. 14A, and FIG. 14C shows a cross-section B-B of FIG. 14A). The removal of the gate electrode 203 can be carried out, for example, by a CMP method generally used for planarization in a semiconductor process. Alternatively, the top of the hole 201 may be covered with a mask, and then the gate electrode 203 may be removed by etching. FIGS. 14A to 14C show an example where the insulating film 202 located on the cap layer 103 is simultaneously removed. However, such removal of the insulating film 202 is not essential, and the insulating film 202 may be allowed to remain on the cap layer 103.

### Step 12a

### Formation of Etching Hole

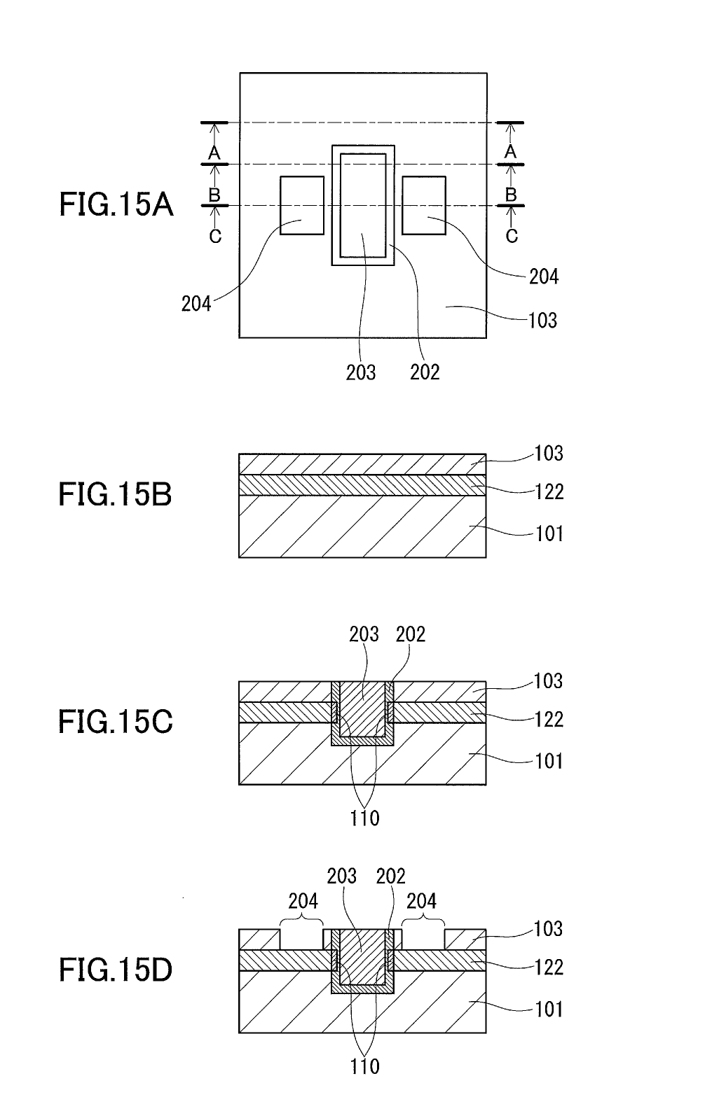

Next, etching holes 204 extending up to the crystalline catalytic metal layer 122 are made in a portion of the cap layer 103 by etching (FIGS. 15A to 15D; FIG. 15B shows a cross-section A-A of FIG. 15A, FIG. 15C shows a cross-section B-B of FIG. 15A, and FIG. 15D shows a cross-section C-C of FIG. 15A). The formation of the holes 204 can be carried out, for example, in the same manner as in a contact hole formation process in a semiconductor process. Specifically, an appropriate mask is formed on the cap layer 103, and the layer 103 is dry-etched. The etching is stopped at the time when the hole formed by the etching has reached the catalytic metal layer 122.

### Step 13a

### Partial Removal of Crystalline Catalytic Metal Layer

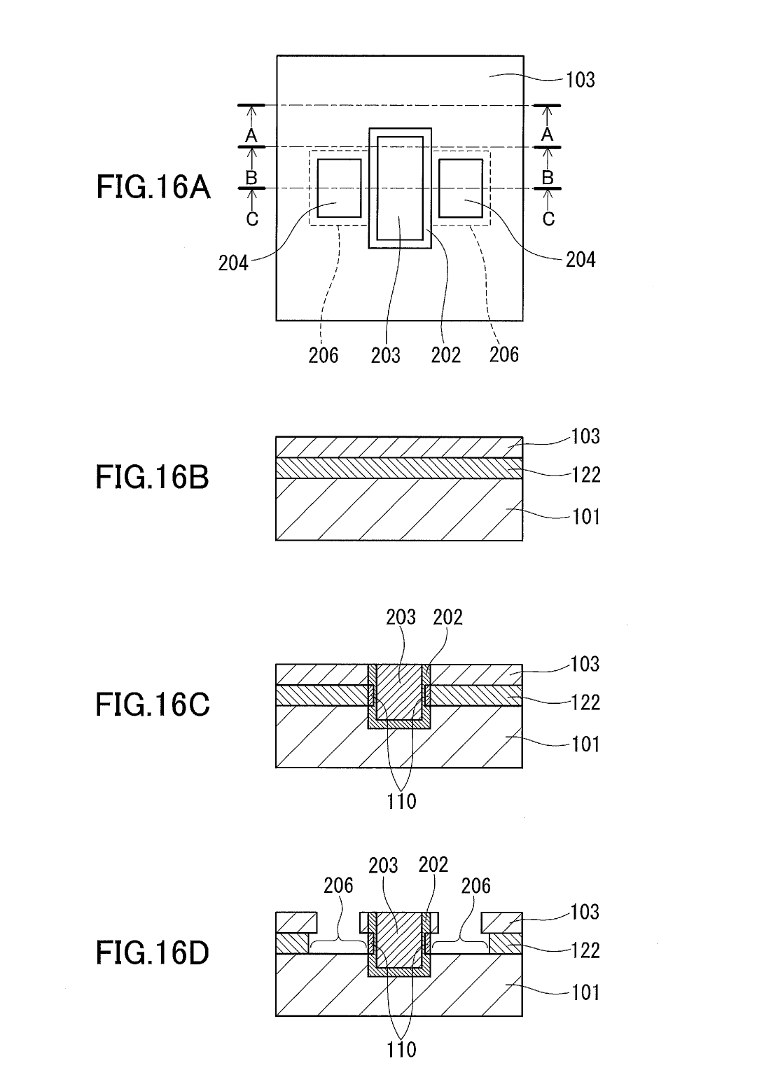

Next, the crystalline catalytic metal layer 122 is partially removed via the holes 204 to form a region where the graphene nanoribbon 110 and the catalytic metal layer 122 are not in contact with each other (FIGS. 16A to 16D; FIG. 16B shows a cross-section A-A of FIG. 16A, FIG. 16C shows a cross-section B-B of FIG. 16A, and FIG. 16D shows a cross-section C-C of FIG. 16A). Regions 206 in FIG. 16D are those formed by removing the catalytic metal layer 122 in the step 13a. In the example of FIG. 16D, a pair of regions 206 are formed at such positions that the regions 206 face each other across the gate electrode 203.

This process can be carried out, for example, by introducing a chemical liquid for dissolving the catalytic metal layer 122 from the etching holes 204 formed in the step 12a. The chemical liquid is, for example, ferric chloride, hydrochloric acid, or a mixture thereof.

### Step 14a

### Formation of Contact Hole

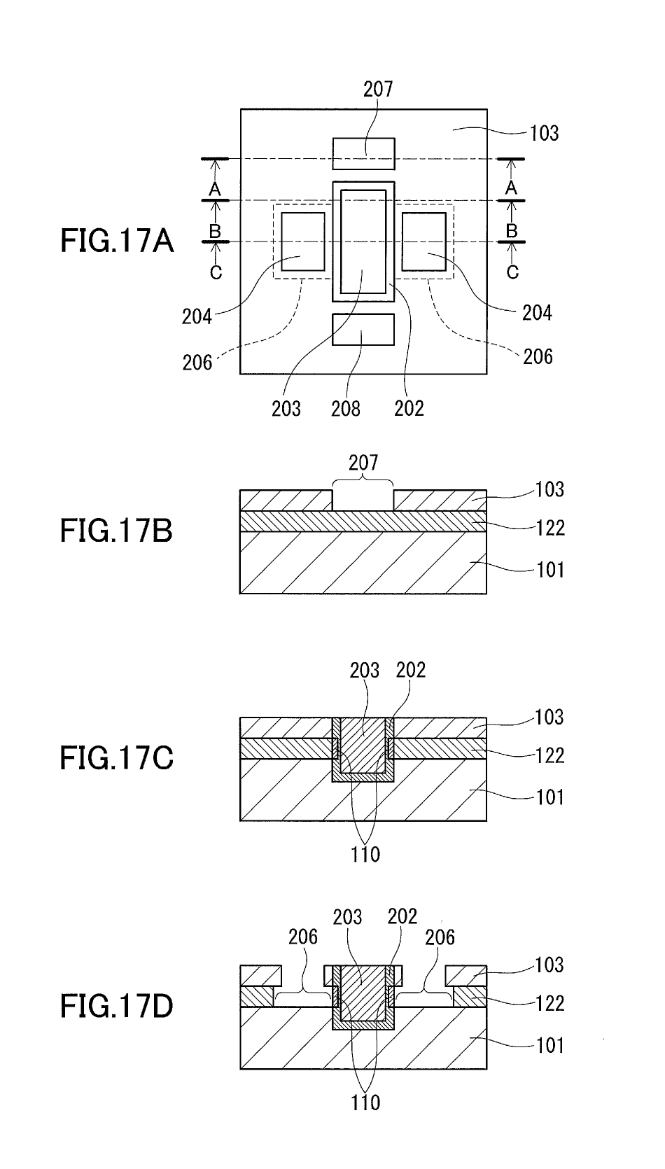

Next, two contact holes 207 and 208 are formed for one device (one gate electrode 203 in the figures) (FIGS. 17A to 17D; FIG. 17B shows a cross-section A-A of FIG. 17A, FIG. 17C shows a cross-section B-B of FIG. 17A, and FIG. 17D shows a cross-section C-C of FIG. 17A). Electrical connection to the catalytic metal layer 122 can be ensured via the contact holes 207 and 208. The pair of contact holes 207 and 208 are formed in such a manner that the regions 206 where the catalytic metal layer 122 is not in contact with the graphene nanoribbon 110 are interposed between the contact holes.

### Step 15a

### Device Isolation

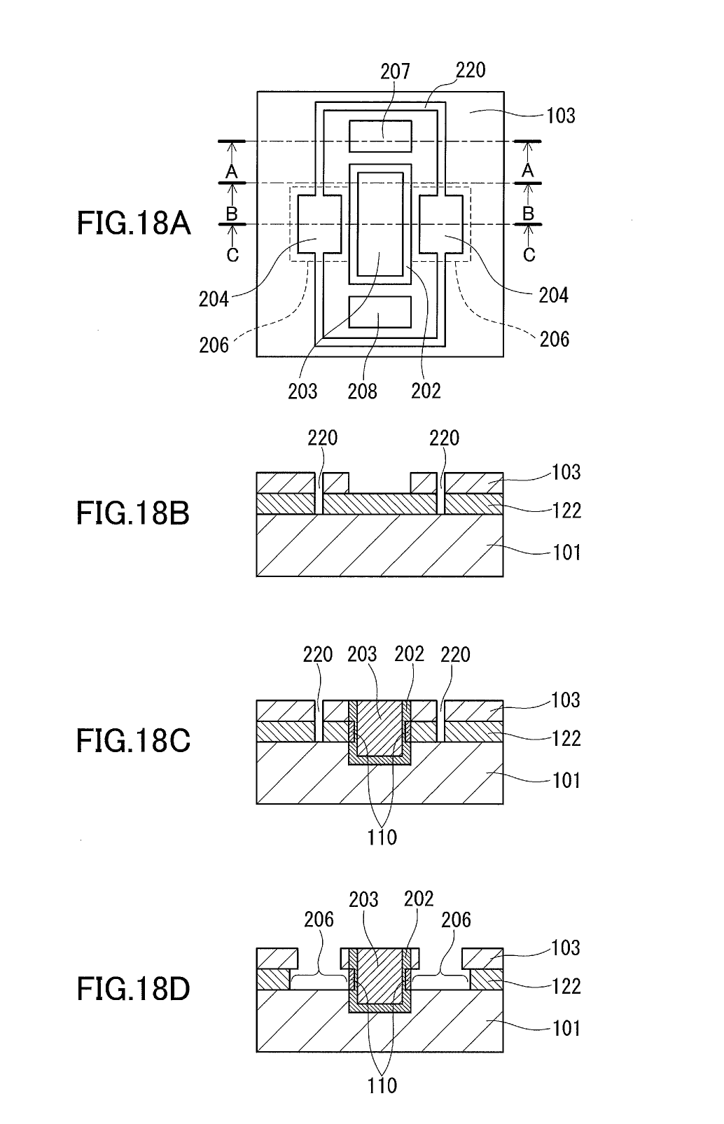

Next, the catalytic metal layer 122 is partially removed to create a state where the catalytic metal layer 122 is divided in two discontinuous catalytic metal layers 122 one of which is in contact with the one contact hole 207 and the other of which is in contact with the other contact hole 208 (FIGS. 18A to 18D; FIG. 18B shows a cross-section A-A of FIG. 18A, FIG. 18C shows a cross-section B-B of FIG. 18A, and FIG. 15D shows a cross-section C-C of FIG. 15A). In the example shown in FIG. 18A, such a state is created by formation of a groove 220 surrounding the contact holes 207 and 208 and connecting to the regions 206 where the catalytic metal layer 122 has been removed.

The one catalytic metal layer 122 and the other catalytic metal layer 122 which are separated by the groove 220 are not continuous as a single metal layer, but are electrically connected via the graphene nanoribbon 110. The graphene nanoribbon 110 has a band gap for allowing the transistor device to function. The electrical conductivity of the graphene nanoribbon 110 can be controlled by a voltage applied to the gate electrode 203 via the insulating layer 202. That is, the structure fabricated according to the above procedure is a field-effect transistor in which the graphene nanoribbon 110 functions as a channel, the pair of the catalytic metal layers 122 separated from each other function respectively as a source and a drain, and the gate electrode 203 functions as a gate electrode.

An integrated circuit can be obtained by carrying out, as necessary, formation of wiring, an interlayer insulating film, or the like, in addition to carrying out the above-described steps. The formation of these components can be achieved by a general semiconductor integrated circuit fabrication process, and the description thereof is therefore omitted.

### Embodiment 3

Embodiment 3 is a method for producing two or more orderly-arranged graphene nanoribbons each having a controlled width and having an edge portion with a controlled structure. This embodiment can be thought of as an applied embodiment of Embodiment 1 described above. The description of matters common to Embodiment 1 is omitted.

### Step 1b

### Preparation of Crystalline Substrate

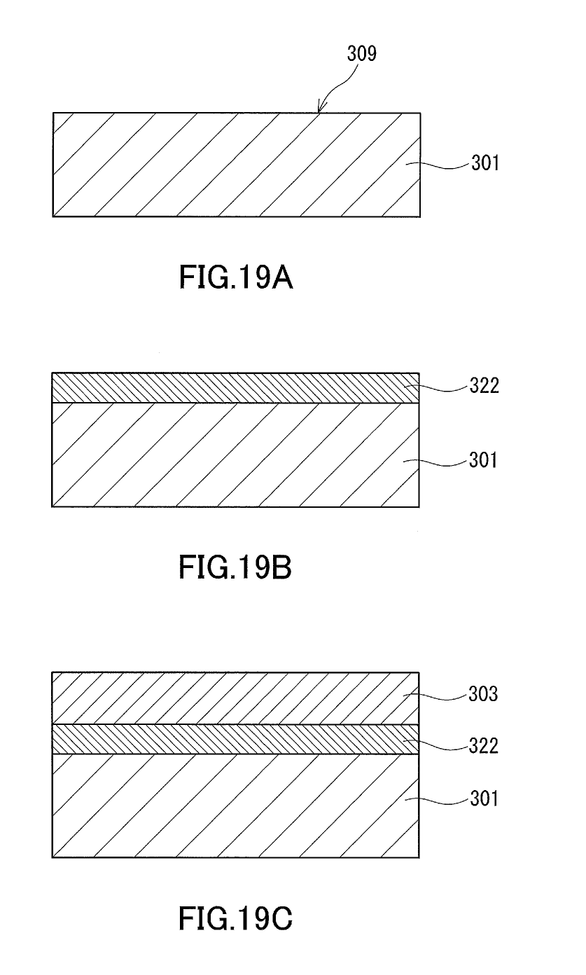

A crystalline substrate 301 having a surface 309 used for growth of a catalytic metal is prepared (FIG. 19A). As in Embodiment 1, in the case where a graphene nanoribbon having an edge portion with a zigzag type structure is fabricated, a (112) plane of a spinel (MgAl₂O₄) single-crystal substrate or a (112) plane of a MgO single-crystal substrate is selected as the surface 309. In the case where a graphene nanoribbon having an edge portion with an armchair type structure is fabricated, a (110) plane of a spinel (MgAl₂O₄) single-crystal substrate or a (110) plane of a MgO single-crystal substrate is selected. An indicator that allows identification of the {111} plane direction of the crystalline substrate 301 may be formed in the substrate. The step 1b is the same as the step 1a of Embodiment 1.

### Step 2b

### Formation of First Crystalline Catalytic Metal Layer

Next, a first crystalline catalytic metal layer 322 having a controlled thickness is formed on the surface 309 of the crystalline substrate 301 in such a manner that the crystal orientation of the layer 322 coincides with the crystal orientation of the substrate 301. The “first” denotes a first-formed catalytic metal layer among two or more crystalline catalytic metal layers formed on the substrate 301 in Embodiment 3. The first catalytic metal layer is the same as the crystalline catalytic metal layer 122 of Embodiment 1.

That is, either the first method or the second method described for the step 2a of Embodiment 1 can be used for formation of the first catalytic metal layer. The step 2a should be referred to for details.

In either method, the thickness of the crystalline catalytic metal layer 322 is made equal to the width of the graphene nanoribbon intended to be fabricated. The width of the graphene nanoribbon can be arbitrarily selected depending on its purpose.

### Step 3b

### Crystallization of First Catalytic Metal Layer

When the first method is selected in the step 2b, a first catalytic metal layer (not shown) deposited on the surface 309 of the substrate 301 is crystallized and converted into the first crystalline catalytic metal layer 322. The step 3b is the same as the step 4a of Embodiment 1. When the second method is selected in the step 2b, the step 3b can be omitted.

In the step 3b, the crystalline catalytic metal layer 322 having the same crystal orientation as the substrate 301 is formed. That is, when the surface 309 of the substrate 301 used for the deposition of the catalytic metal is a (110) plane, crystallization takes place in such a manner that the (110) plane of nickel or copper is parallel to the surface 309. When the surface 309 used for the growth of the catalytic metal is a (112) plane, crystallization takes place in such a manner that the (112) plane of nickel or copper is parallel to the surface 309.

### Step 4b

### Formation of Crystalline Spacer Layer

Next, a crystalline spacer layer 303 is deposited on the catalytic metal layer 322 (FIG. 19C). The crystalline spacer layer 303 is required to have three characteristics.

The first characteristic is that the crystalline spacer layer 303 has the same crystal orientation as the catalytic metal layer 322. The second characteristic is that (a crystal of) an additional crystalline catalytic metal layer having the same crystal orientation as the spacer layer 303 can be grown on the layer 303. The third characteristic is that graphene is less likely to grow on a side wall of the spacer layer 303 exposed in a subsequent step than on side walls of catalytic metal layers including the first catalytic metal layer 322.

An example of materials that possess these three characteristics is spinel (MgAl₂O₄).

The deposition of the spacer layer 303 is carried out, for example, by a sputtering method or an electron beam evaporation method. In order to facilitate the crystallization of the spacer layer 303, the substrate temperature during deposition is desirably a high temperature of 500° C. or more. The spacer layer 303 need not be crystallized at the completion of deposition, and crystallization may be performed by the time an additional catalytic metal layer is formed on the spacer layer 303. The crystallization can be carried out, for example, by heating treatment. Whether or not the spacer layer 303 has been crystallized can be confirmed by X-ray diffraction or electron beam diffraction.

When spinel (MgAl₂O₄) is used, the spacer layer 303 grows in such a manner that its crystal orientation coincides with the crystal orientation of the catalytic metal layer underlying the spacer layer 303. That is, the (110) plane of spinel (MgAl₂O₄) grows on and parallel to the (110) plane of copper or nickel, and the (112) plane of spinel (MgAl₂O₄) grows on and parallel to the (112) plane of copper or nickel.

### Step 5b

### Formation of Additional Catalytic Metal Layer

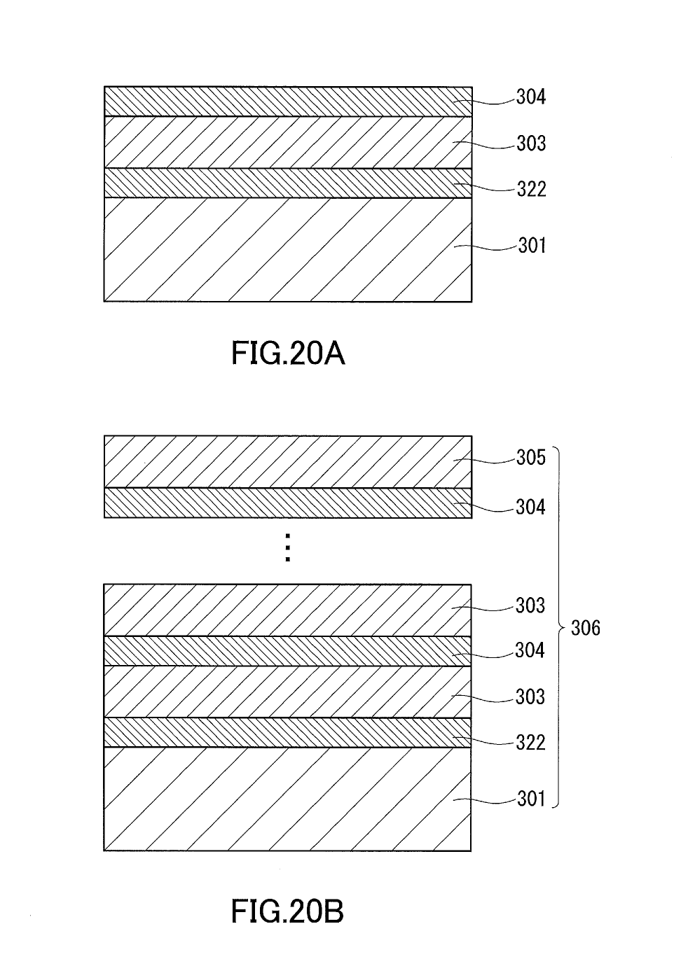

Next, an additional crystalline catalytic metal layer 304 having a controlled thickness is formed on the spacer layer 303 in such a manner that the crystal orientation of the layer 304 coincides with the crystal orientation of the spacer layer 303 (FIG. 20A).

The material composing the additional catalytic metal layer 304 is copper or nickel. This material is desirably the same as the material of the first catalytic metal layer 302.

The formation of the additional catalytic metal layer 304 can be carried out in the same manner as in the formation of the first catalytic metal layer 302. That is, the first method or the second method described above for the step 2b can be selected.

The thickness of the additional catalytic metal layer 304 is made equal to the width of the graphene nanoribbon intended to be fabricated on the side wall of the layer 304. In the case of a combination of the additional catalytic metal layer 304 and the first catalytic metal layer 302 that have the same thickness, two or more graphene nanoribbons having the same width can be fabricated so as to be parallel to each other. On the other hand, in the case of a combination of the metal layers having different thicknesses, two or more graphene nanoribbons having different widths can be fabricated so as to be parallel to each other. For example, the former combination is suitably selected when it is intended to enhance the channel driving force of a transistor, while the latter combination is suitably selected when it is intended to arrange graphene nanoribbons having different optical properties.

Two or more additional catalytic metal layers 304 can be formed by repeating the formation of the spacer layer 303 and the formation of the additional catalytic metal layer 304. All of the additional catalytic metal layers 304 may have the same thickness or one or more of the additional catalytic metal layers 304 may have different thicknesses from each other.

### Step 6b

### Crystallization of Additional Catalytic Metal Layer

When the first method is selected in the step 5b, the catalytic metal deposited on the spacer layer 303 is crystallized. The step 6b can be carried out in the same manner as in the step 3b. When the second method is selected in the step 5b, the step 6b can be omitted.

### Step 7b

### Formation of Cap Layer

Next, a cap layer 305 is formed on the stack of the substrate 301, the catalytic metal layers 322 and 304, and the spacer layer 303 (FIG. 20B). In the example of FIG. 20B, the cap layer 305 is deposited on the topmost additional catalytic metal layer 304. The material composing the cap layer 305 is a material having the feature that graphene is less likely to grow on a side wall surface of the cap layer 305 in the selective graphene growth step described later. This requirement is the same as that for the cap layer 103 in Embodiment 1. That is, the materials and deposition procedure described in Embodiment 1 can be employed for the cap layer 305. As a result of the formation of the cap layer 305, a stack (layered structure) 306 is completed. The cap layer 305 and the spacer layer 303 may be composed of the same material, and two or more cap layers 305 may be formed as necessary.

### Step 8b

### Formation of Etching Mask

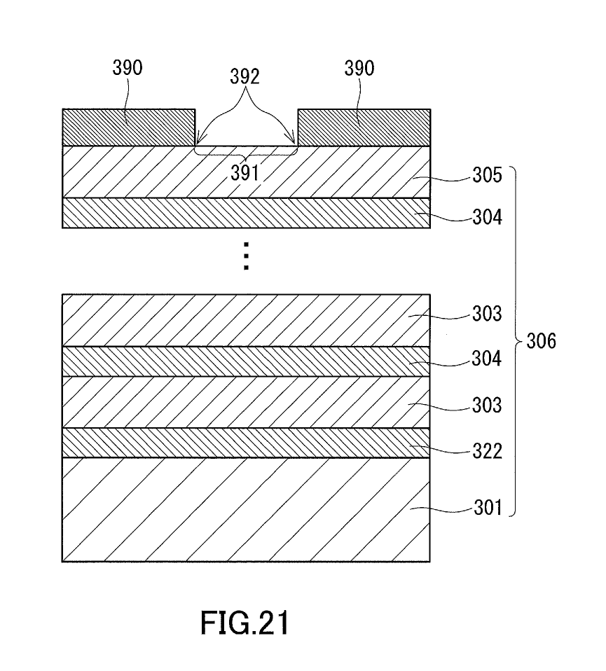

Next, an etching mask 390 is formed (FIG. 21). The mask 390 defines a region 391 to be etched at the time of etching of the stack 306 in the step 9b, and a region not to be etched. The mask pattern 390 is set in such a manner that, in the portion where a graphene nanoribbon is intended to be fabricated, a boundary line 392 between the two regions is parallel to the {111} planes of the catalytic metal layers 322 and 304.

When the material combination described above for the substrate 301, the catalytic metal layers 322 and 304, and the spacer layer 303 is employed, the {111} planes of all the catalytic metal layers 322 and 304 are parallel to the {111} plane of the substrate 301. Therefore, when the mask 390 is selected so as to be parallel to the {111} plane of the substrate 301, the boundary 392 is formed parallel to the {111} planes of the catalytic metal layers 322 and 304.

### Step 9b

### Etching

Next, etching process is carried out to expose the {111} planes of the catalytic metal layers 322 and 304 as side walls 312 and 314. The crystal orientations of the catalytic metal layers 322 and 304 coincide with the crystal orientation of the substrate 301. The {111} plane of the catalytic metal layer 322 and the {111} plane of the additional catalytic metal layer 304 are parallel to each other, and are each orthogonal to the surface 309 used for the growth of the catalytic metal. Therefore, the {111} planes of the catalytic metal layers 322 and 304 can be exposed by using the mask 390 fabricated in the step 8b to carry out etching in the direction perpendicular to the surface 309 used for the growth of the catalytic metal.

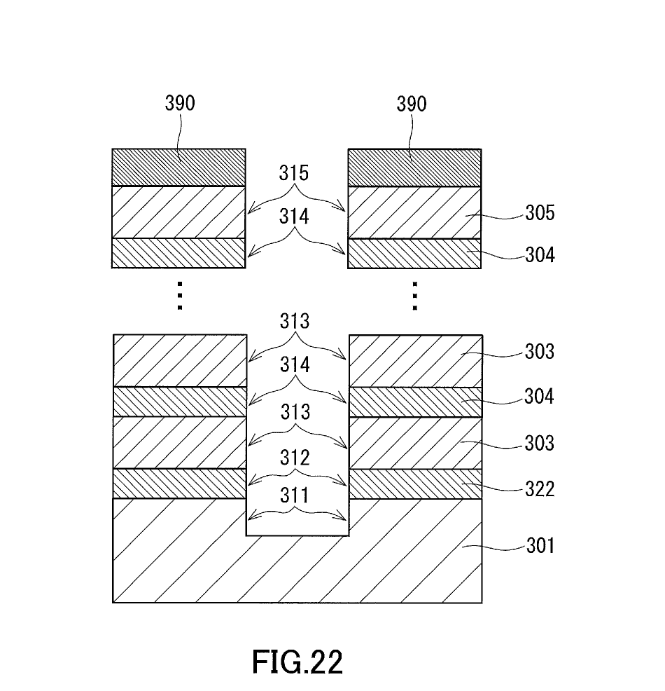

The etching is carried out, for example, up to the boundary face between the substrate 301 and the first catalytic metal layer 322 so that the side wall 312 or 314 of at least one of the catalytic metal layers 322 and 304 is exposed. The substrate 301 may be etched so as to be fully penetrated, may be partially etched in the thickness direction, or may not be etched at all. In the example shown in FIG. 22, etching is carried out up to a part of the substrate 301, so that the side wall 311 of the substrate 301, the side wall 313 of the spacer layer 303, and the side wall 315 of the cap layer 305 are exposed.

The etching can be carried out, for example, by a dry etching method or an ion milling method.

### Step 10b

### Annealing Treatment and Surface Reduction

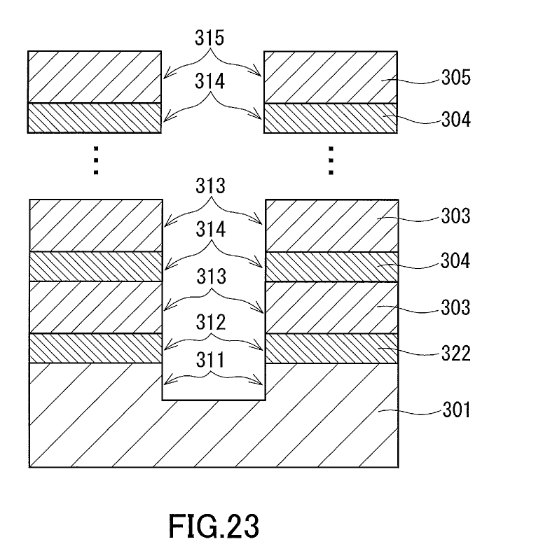

Next, the mask 390 is removed, and an annealing treatment and a surface reduction treatment of the side walls 312 and 314 of the catalytic metal layers 322 and 304 are carried out (FIG. 23). Thus, crystallinity restoration and surface reduction are achieved. The step 10b is the same as the step 7a of Embodiment 1. Even when two or more catalytic metal layers are formed, the annealing treatment and surface reduction treatment can be carried out in the same manner as when only one catalytic metal layer is formed.

In the case where a (112) plane is selected as the surface 309 used for the growth of the catalytic metal, the atomic arrangement in the surfaces of the side walls 312 and 314 is brought into the state shown in FIG. 7 as a result of the annealing treatment and surface reduction. In the case where a (110) plane is selected as the surface 309 used for the growth of the catalytic metal, the atomic arrangement is brought into the state shown in FIG. 8.

### Step 11b

### Selective Growth of Graphene

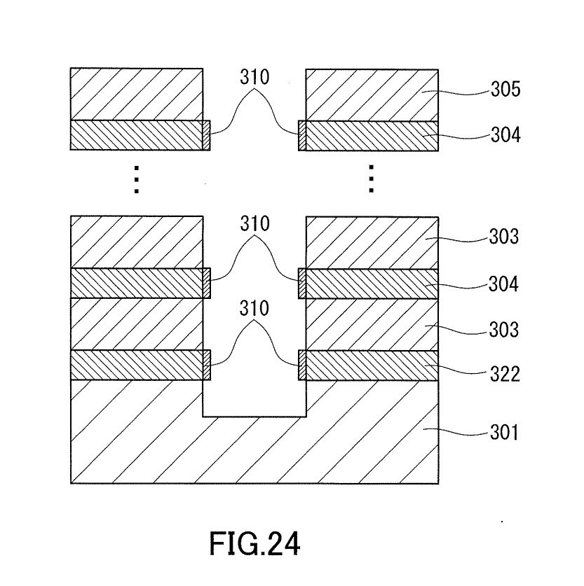

Next, graphenes 310 are grown selectively on the exposed side walls 312 and 314 of the catalytic metal layers 322 and 304 (FIG. 24). The step 11b is the same as the step 8a of Embodiment 1. That is, the graphene nanoribbons 310 are grown only on the side walls 312 and 314 by a CVD method.

The structure of the edge portion of the graphene nanoribbon 301 reflects the atomic arrangement in the surface of the side wall 312 or 314. That is, in the case of the atomic arrangement shown in FIG. 7, a nanoribbon having an edge portion with a zigzag type structure as shown in FIG. 9 grows. On the other hand, in the case of the atomic arrangement shown in FIG. 8, a nanoribbon having an edge portion with an armchair type structure as shown in FIG. 10 grows.

Which of the atomic arrangements the surfaces of the side walls 312 and 314 have is determined by selection of the surface 309 used for the growth of the catalytic metal. That is, in the case where a (112) plane is selected as the surface 309, a nanoribbon having an edge portion with a zigzag type structure grows. On the other hand, in the case where a (110) plane is selected as the surface 309, a nanoribbon having an edge portion with an armchair type structure grows.

Since the catalytic metal layers 322 and 304 are parallel to each other, the graphene nanoribbons 310 grown on the side walls 312 and 314 are also parallel to each other.

The widths of the graphene nanoribbons 310 formed are equal to the thicknesses of the catalytic metal layers 322 and 304. The thicknesses can be controlled, and can be adjusted to 10 nm or less as necessary.

The positions on the substrate 301 where the graphene nanoribbons 310 are formed can be controlled by the pattern of the mask 390.

As described above, in Embodiment 3, two or more graphene nanoribbons each having a controlled width and having an edge portion with a controlled structure are formed parallel to each other at desired positions on the substrate.

The basic difference between Embodiment 1 and Embodiment 3 is whether one graphene nanoribbon is formed or two or more graphene nanoribbons are formed. Therefore, a transistor using the graphene nanoribbons fabricated in Embodiment 3 can be fabricated by employing the same procedure as described in Embodiment 2.

A graphene nanoribbon fabricated by the production method of the present disclosure has a controlled width and an edge portion with a controlled structure, and is located at a desired position on a substrate. Since the width can be controlled to be 10 nm or less, a band gap sufficient for use in a semiconductor device can be achieved. The graphene nanoribbon can be used, for example, as a channel of a transistor.

The present invention may be embodied in other forms without departing from the spirit or essential characteristics thereof. The embodiments disclosed in this specification are to be considered in all respects as illustrative and not limiting. The scope of the present invention is indicated by the appended claims rather than by the foregoing description, and all changes which come within the meaning and range of equivalency of the claims are intended to be embraced therein.

What is claimed is:

1. A method for producing a graphene nanoribbon, comprising the steps of:
forming a crystalline catalytic metal layer composed of copper or nickel on a (110) plane or a (112) plane of a MgAl₂O₄ single-crystal substrate or a MgO single-crystal substrate, with a thickness of the crystalline catalytic metal layer being controlled and with a crystal orientation of the crystalline catalytic metal layer being controlled so that the crystal orientation coincides with a crystal orientation of the single-crystal substrate;
forming a cap layer composed of an oxide on the formed catalytic metal layer;
exposing a {111} plane of the crystalline catalytic metal layer as a side wall by etching a stack including the substrate, the catalytic metal layer, and the cap layer; and
growing graphene selectively on the exposed side wall by chemical vapor deposition.

2. A method for producing a graphene nanoribbon, comprising the steps of:
forming a crystalline catalytic metal layer composed of copper or nickel on a (110) plane or a (112) plane of a MgAl₂O₄ single-crystal substrate or a MgO single-crystal substrate, with a thickness of the crystalline catalytic metal layer being controlled and with a crystal orientation of the crystalline catalytic metal layer being controlled so that the crystal orientation coincides with a crystal orientation of the single-crystal substrate;
forming at least one pair of a crystalline spacer layer composed of MgAl₂O₄ and an additional crystalline catalytic metal layer that are stacked in this order on the formed catalytic metal layer, with control of a crystal orientation of the spacer layer, a thickness of the additional catalytic metal layer, and a crystal orientation of the additional catalytic metal layer;
forming a cap layer composed of an oxide on a stack including the substrate, the catalytic metal layer, the spacer layer, and the additional catalytic metal layer;
exposing a (111) plane of at least one layer selected from the catalytic metal layer and the additional catalytic metal layer as a side wall by etching the stack; and
growing graphene selectively on the exposed side wall by chemical vapor deposition, wherein
the control of the crystal orientations of the spacer layer and the additional catalytic metal layer is carried out so that the crystal orientation of the spacer layer coincides with the crystal orientation of the catalytic metal layer underlying said spacer layer, and that the crystal orientation of the additional catalytic metal layer coincides with the crystal orientation of the spacer layer underlying said additional catalytic metal layer.

3. A method for producing a graphene nanoribbon, comprising the steps of:
forming a layer composed of copper or nickel on a (110) plane or a (112) plane of a MgAl₂O₄ single-crystal substrate or a MgO single-crystal substrate, with a thickness of the layer being controlled and with a crystal orientation of the layer being controlled so that the crystal orientation coincides with a crystal orientation of the single-crystal substrate;
forming a cap layer composed of an oxide on the formed layer composed of copper or nickel;
exposing a {111} plane of the layer composed of copper or nickel as a side wall by etching a side surface of the layer; and
growing graphene selectively on the exposed side wall.

4. A method for producing a graphene nanoribbon, comprising the steps of:
forming a layer composed of copper or nickel on a (110) plane or a (112) plane of a MgAl₂O₄ single-crystal substrate or a MgO single-crystal substrate, with a thickness of the layer being controlled and with a crystal orientation of the layer being controlled so that the crystal orientation coincides with a crystal orientation of the single-crystal substrate;
forming, on the formed layer composed of copper or nickel, at least one pair of a MgAl₂O₄ single-crystal layer and a layer composed of copper or nickel that are stacked in this order;
forming a cap layer composed of an oxide on a stack including the substrate, the layer composed of copper or nickel, and the MgAl₂O₄ single-crystal layer;
exposing a {111} plane of the layer composed of copper or nickel as a side wall by etching a side surface of the layer; and
growing graphene selectively on the exposed side wall.

5. A method for producing a graphene nanoribbon, comprising the steps of:
preparing a stack including: a MgAl₂O₄ single-crystal substrate or a MgO single-crystal substrate; and a layer formed on the substrate and composed of copper or nickel, the stack including a {111} plane as a plane perpendicular to a principal surface of the layer;
exposing a {111} plane of the layer composed of copper or nickel as a side wall; and
growing graphene on the exposed side wall.

6. A method for producing a transistor, comprising the step of forming a transistor using the graphene nanoribbon obtained by the production method according to claim 1 as a channel.
